(19) United States
(12) Patent Application Publication
(10) Pub. No.: US 2008/0073680 A1
(43) Pub. Date: Mar. 27, 2008

(54) Semiconductor device and fabrication process thereof

(75) Inventor: Wensheng Wang, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/790,548

(22) Filed: Apr. 26, 2007

(30) Foreign Application Priority Data
Sep. 21, 2006 (JP) 2006-255971

(51) Int. Cl. H01L 29/78; H01L 21/00

(52) U.S. Cl. 257/295; 438/3; 257/E29.255; 257/E21.085

(57) ABSTRACT

A semiconductor device includes a conductive oxygen diffusion barrier film formed over a substrate, a metal oxide film formed over the conductive oxygen diffusion barrier film for suppressing diffusion of Pb, a lower electrode containing Pt formed over the metal oxide film, a ferroelectric film containing Pb and formed over the lower electrode, and an upper electrode formed over the ferroelectric film.

### CROSS-REFERENCE TO RELATED APPLICATION

The present application is based on Japanese priority application No. 2006-255971 filed on Sep. 21, 2006, the entire contents of which are hereby incorporated by reference.

### BACKGROUND OF THE INVENTION

The present invention generally relates to semiconductor devices and more particularly to a semiconductor device having a ferroelectric capacitor and fabrication process thereof.

A ferroelectric memory is a non-volatile voltage-driven semiconductor memory device and is characterized by preferable feature of high operational speed, low electric power consumption and non-volatility of information in that the information held therein is retained even when the electric power is turned off. Ferroelectric memories are already used in IC cards and other portable electronic apparatuses.

FIG. 1 is a cross-sectional diagram showing the construction of a ferroelectric memory device 10 called stacked type device.

Referring to FIG. 1, the ferroelectric memory device 10 is a so-called 1T1C device and includes two memory cell transistors formed in a device region 11A defined on a silicon substrate 11 by a device isolation region 11I such that the two memory cell transistors share a bit line.

More specifically, there is formed an n-type well in the silicon substrate 11 as the device region 11A, wherein there are formed, on the device region 11A, a first MOS transistor having a polysilicon gate electrode 13A and a second MOS transistor having a polysilicon gate electrode 13B via respective gate insulation films 12A and 12B.

In the silicon substrate 11, there are formed LDD regions 11a and 11b of p⁻-type in correspondence to respective sidewalls of the gate electrode 13A, and there are further formed LDD regions 11c and 11d of p⁻-type in correspondence to respective sidewalls of the gate electrode 13B. Thereby, the first and second MOS transistors are formed commonly in the device region 11A, and thus, the same p-type diffusion region is used as the LDD region 11b and the LDD region 11c.

On the polysilicon gate electrodes 13A and 13B, there are formed silicide layers 14A and 14B, respectively, and there are further formed sidewall insulation films on the sidewall surfaces of the polysilicon gate electrode 13A and on the sidewall surfaces of the polysilicon gate electrode 13B, respectively.

Furthermore, diffusion regions 11e and 11f of p⁺-type are formed in the silicon substrate 11 at respective outer sides of the sidewall insulation films of the gate electrode 13A, and diffusion regions 11g and 11h of p⁺-type are formed in the silicon substrate 11 at respective outer sides of the sidewall insulation films of the gate electrode 13B. Furthermore, diffusion regions 11f and 11g are formed by the same p⁺-type diffusion region.

Further, on the silicon substrate 11, there is formed an SiON film 15 so as to cover the gate electrode 13A including the silicide layer 14A and the sidewall insulation films of the gate electrode 13A and so as to cover the gate electrode 13B including the silicide layer 14B and the sidewall insulation films on the gate electrode 13B, and an interlayer insulation film 16 of SiO2 is formed on the SiON film 15. Further, contact holes 16A, 16B and 16C are formed in the interlayer insulation film 16 so as to expose the diffusion region 11e, the diffusion region 11f (the diffusion region 11g), and the diffusion region 11h, respectively, wherein via-plugs 17A, 17B and 17C of W (tungsten) are formed in the respective contact holes 16A, 16B and 16C via adhesive layers 17a, 17b and 17c, wherein each of the adhesive layers 17a, 17b and 17c is formed by lamination of a Ti film and a TiN film.

Further, on the interlayer insulation film 16, there is formed a first ferroelectric capacitor C1 in which a lower electrode 18A, a polycrystalline ferroelectric film 19A and an upper electrode 20A are stacked in contact with the tungsten plug 17A. Similarly, a second ferroelectric capacitor C2 is formed on the interlayer insulation film 16 by stacking of a lower electrode 18C, a polycrystalline ferroelectric film 19C and an upper electrode 20C in contact with the tungsten plug 17C.

Further, on the interlayer insulation film 16, there is formed a hydrogen barrier film 21 of Al₂O₃ so as to cover the ferroelectric capacitors C1 and C2, and a next interlayer insulation film 22 is formed further on the hydrogen barrier film 21.

Further, in the interlayer insulation film 22, there are formed a contact hole 22A exposing the upper electrode 20A of the ferroelectric capacitor C1, a contact hole 22B exposing the via-plug 17B, and a contact hole 22C exposing the upper electrode 20C of the ferroelectric capacitor C2, wherein the contact holes 22A-22C are formed respectively with tungsten plugs 23A, 23B and 23C via respective adhesion layers 23a, 23b and 23c formed by lamination of a Ti film and a TiN film.

Further, Al interconnection patterns 24A, 24B and 24C are formed on the interlayer insulation film 22 respectively in correspondence to the tungsten plugs 23A, 23B and 23C with a barrier metal film of the Ti/TiN layered structure.

### REFERENCES

Patent Reference 1 Japanese Laid-Open Patent Application 2003-92391

Patent Reference 2 Japanese Laid-Open Patent Application 2004-153006

Patent Reference 3 Japanese Laid-Open Patent Application 2003-318371

Patent Reference 4 Japanese Laid-Open Patent Application 2003-209179

Patent Reference 5 Japanese Laid-Open Patent Application 2003-51582

Patent Reference 6 Japanese Laid-Open Patent Application 6-326270

Patent Reference 7 Japanese Laid-Open Patent Application 8-288239

### SUMMARY OF THE INVENTION

Meanwhile, with the ferroelectric memory of FIG. 1, or the like, it should be noted that the crystal orientation of the ferroelectric films 19A and 19C used for the ferroelectric capacitor insulation film is of extreme importance. The ferroelectrics such as PZT have a perovskite structure of tetragonal system and show ferroelectricity phenomenon as a result of displacement of the metal atom such as Ti or Zr in the perovskite structure in the c-axis direction. Thus, with the ferroelectric capacitor of the construction in which the ferroelectric film is sandwiched between the upper and lower electrodes, as in the case of the ferroelectric memory 10 of FIG. 1, it is ideal that the ferroelectric film has a (001) orientation in which the direction of the electric field is aligned parallel to the c-axis direction of the ferroelectrics. In the case the ferroelectric film has a (100) orientation, on the other hand, there appears no ferroelectricity.

However, the difference between the c-axis and the a-axis small in the perovskite film, and there arises a situation, when the PZT film is formed by a usual manufacturing method, that the crystal grains of the (001) orientation and the crystal grains of the (100) orientation occur more or less with the same proportion. Further, by taking into consideration the fact that there may be formed crystal grains of other directions, the proportion of the crystal grains that contribute to the operation of the ferroelectric capacitor is small. Under these circumstances, it has been practiced in the art of ferroelectric memory, to form each of the ferroelectric films 19A and 19C in the form of predominantly (111)-oriented film. Thereby the direction of orientation is aligned in the <111> direction and large switching electric charge QSW is guaranteed.

Thus, in view of the situation noted above, it has been practiced in the art of ferroelectric memory to form a Pt film, used for the lower electrode of the ferroelectric capacitor, on an orientation control film such as a self-aligned Ti film with a (111) orientation via a conductive oxygen diffusion barrier film such as a TiAlN film, and a ferroelectric film such as a PZT film is formed thereon with the (111) orientation. Here, it should be noted that the self-oriented Ti film shows a (002) orientation. Further, the TiAlN oxygen diffusion barrier film suppresses the invasion of oxygen in the ferroelectric film into the W plug.

On the other hand, such a ferroelectric memory is also imposed with the requirement of miniaturization and increase of integration density, and thus, there are made attempts to form the ferroelectric film with an MOCVD process having characteristically excellent step coverage.

With an MOCVD process, a ferroelectric film is formed generally at a high temperature of 600° C. or more.

On the other hand, with a ferroelectric film formed by such an MOCVD process, there arises a problem in that the orientation of the ferroelectric crystals becomes unstable particularly in the case temperature elevation process is conducted in an Ar gas ambient. When this occurs, the proportion of the (111) oriented PZT crystals becomes remarkably low and there arises a problem that the obtained ferroelectric film has extremely poor electric characteristics in terms of switching electric charges, and the like.

In order to solve this problem, there is a proposal of conducting the MOCVD film formation of the ferroelectric film by raising the temperature in an oxygen-containing ambient. However, the ferroelectric film that has experienced temperature elevation process in such an oxygen-containing ambient tends to cause a problem, particularly in the case the ferroelectric film is the one that contains Pb such as PZT or PLZT, in that cracking develops at an interface between the lower electrode and a TiAlN oxygen diffusion barrier film underneath the lower electrode as a result of the Pb atoms in the ferroelectric film causing penetration through the lower electrode and reacting with the TiAlN oxygen barrier film.

In order to suppress the cracking of the lower electrode, there is a need of using Ir or Ru, while the use of Ir or Ru for the lower electrode raises the problem that the orientation of the ferroelectric film becomes poor as shown in FIGS. 2A and 2B. For example, the orientation of the PZT film becomes poor and there is also caused the problem of increased wafer-to-wafer variation. Here, it should be noted that FIG. 2A shows the integral intensity of PZT (111) orientation of a PZT film constituting the ferroelectric film, while FIG. 2B shows the PZT (222) orientation rate defined as

(222)/((100)+(010)+(222)).

It should be noted that FIGS. 2A and 2B show the result for the central part of the substrate. In the peripheral part of the substrate, both the integral intensity and the orientation rate are deteriorated further.

Further, with such a PZT film formed on the Ir lower electrode by an MOCVD process, it should be noted that there appears an irregular surface morphology as shown in FIG. 3A, while such an irregular surface morphology suggests occurrence of abnormal growth of IrOx crystals caused by the action of the oxidizing ambient or the like used at the time of formation of the PZT film. When an upper electrode is formed in the state where anomaly is caused in the morphology of the PZT film surface, there arises a problem of increase of leakage current. Further, there arises a problem of severe degradation of the capacitor characteristics during the fabrication process of the ferroelectric memory. Further, such anomaly of the surface morphology is believed to be the cause of the variation of orientation in the ferroelectric capacitor explained previously with reference to FIGS. 2A and 2B.

In view of the foregoing, there is proposed a technology of forming a ferroelectric underlayer of PZT, or the like, on the lower electrode by a sputtering process or a sol-gel process and form a ferroelectric film thereon by an MOCVD process.

FIG. 3B shows the surface morphology of the PZT film formed by an MOCVD process on a PZT underlayer film formed by a sputtering process. Referring to FIG. 3B, it can be seen that the PZT film has a flat and satisfactory surface morphology.

With the PZT film of FIG. 2B, Pt is used for the lower electrode, and because of this, it is possible to control the orientation of the PZT film in the (111) orientation. On the other hand, because of high film-forming temperature of MOCVD process, Pb tends to cause diffusion from the PZT film with such a process, and there is a concern that a compound such as PbPt₂ may be formed when Pb thus caused diffusion has caused reaction with Pt constituting the lower electrode. Further, there are cases in which the Pb atoms penetrate through the lower electrode and cause reaction with the TiAlN oxygen diffusion barrier film. Thus, there are cases in which cracking shown in FIG. 4 is caused between the Pt lower electrode and the TiAlN oxygen diffusion barrier film.

In a first aspect, the present invention provides a semiconductor device, comprising: a conductive oxygen diffusion barrier film formed over a substrate; a metal oxide film formed over said conductive oxygen diffusion barrier film and suppressing diffusion of Pb; a lower electrode containing Pt formed over said metal oxide film; a ferroelectric film containing Pb and formed over said lower electrode; and an upper electrode formed over said ferroelectric film.

In another aspect, the present invention provides a method for fabricating a semiconductor device having a ferroelectric capacitor, comprising the steps of: forming a MOS transistor over a silicon substrate; depositing an interlayer insulation film over said silicon substrate so as to cover said MOS transistor; forming a via-plug in said interlayer insulation film in contact with a diffusion region of said MOS transistor; forming a conductive oxygen diffusion barrier film over said via-plug; forming a metal oxide film suppressing diffusion of Pb over said conductive oxygen diffusion barrier film; forming a lower electrode film containing Pt as a primary component over said metal oxide film; forming a ferroelectric film containing Pb over said lower electrode film; and forming an upper electrode over said ferroelectric film.

According to the present invention, it becomes possible to suppress the cracking at the interface between the oxygen diffusion barrier film and the lower electrode and it becomes also possible to control the orientation of the ferroelectric film in the desired (111) orientation as a result of use of the Pt lower electrode Further, by forming the ferroelectric film by a first film part formed by a sputtering process or a sol-gel process and a second film part formed by an MOCVD process, the ferroelectric film shows excellent surface morphology and the ferroelectric capacitor shows excellent electric characteristics.

Other objects and further features of the present invention will become apparent from the following detailed description when read in conjunction with the attached drawings.

### BRIEF DESCRIPTION OF THE DRAWINGS

FIG. 1 is a diagram showing the construction of a ferroelectric memory according to a related art of the present invention;

FIGS. 2A and 2B are diagrams explaining the problems addressed by the present invention;

FIG. 3A is another diagram explaining the problem addressed by the present invention;

FIG. 3B is a further diagram explaining the problem addressed by the present invention;

FIGS. 5A-5E are diagrams showing the fabrication process of a ferroelectric capacitor according to a first embodiment of the present invention;

FIGS. 6A-6V are diagrams showing the fabrication process of a ferroelectric capacitor according to a second embodiment of the present invention;

FIG. 7 is a diagram showing the construction of a ferroelectric memory according to a third embodiment of the present invention;

FIG. 8 is a diagram showing the construction of a ferroelectric memory according to a modification of the third embodiment; and

FIG. 9 is a diagram showing the construction of a ferroelectric memory according to a fourth embodiment of the present invention.

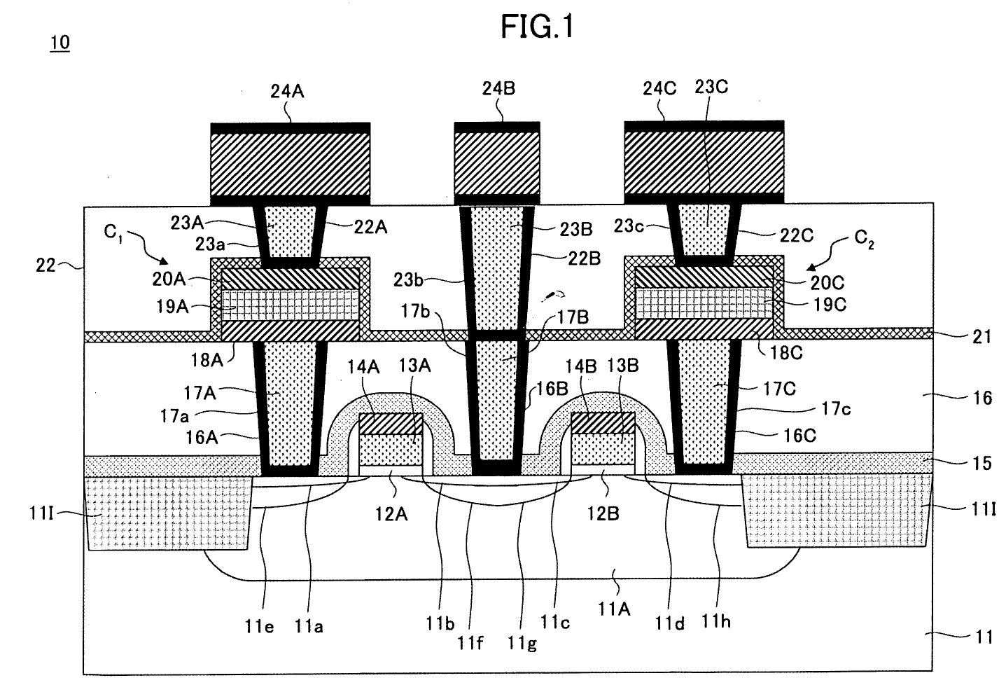

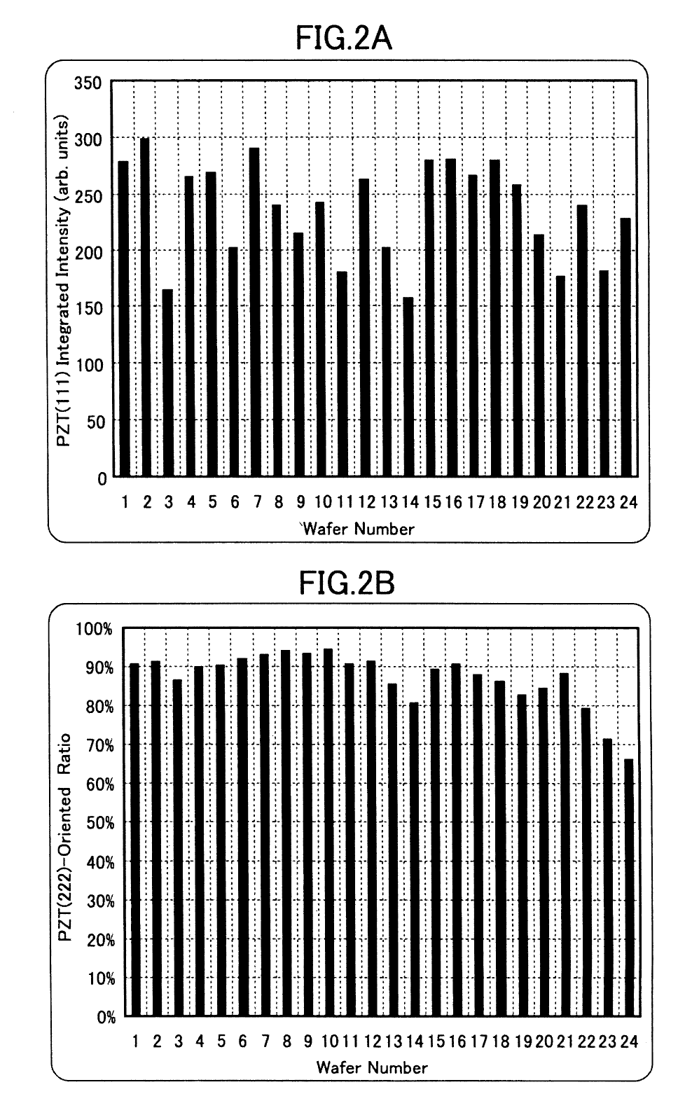

### DETAILED DESCRIPTION OF THE INVENTION

### First Embodiment

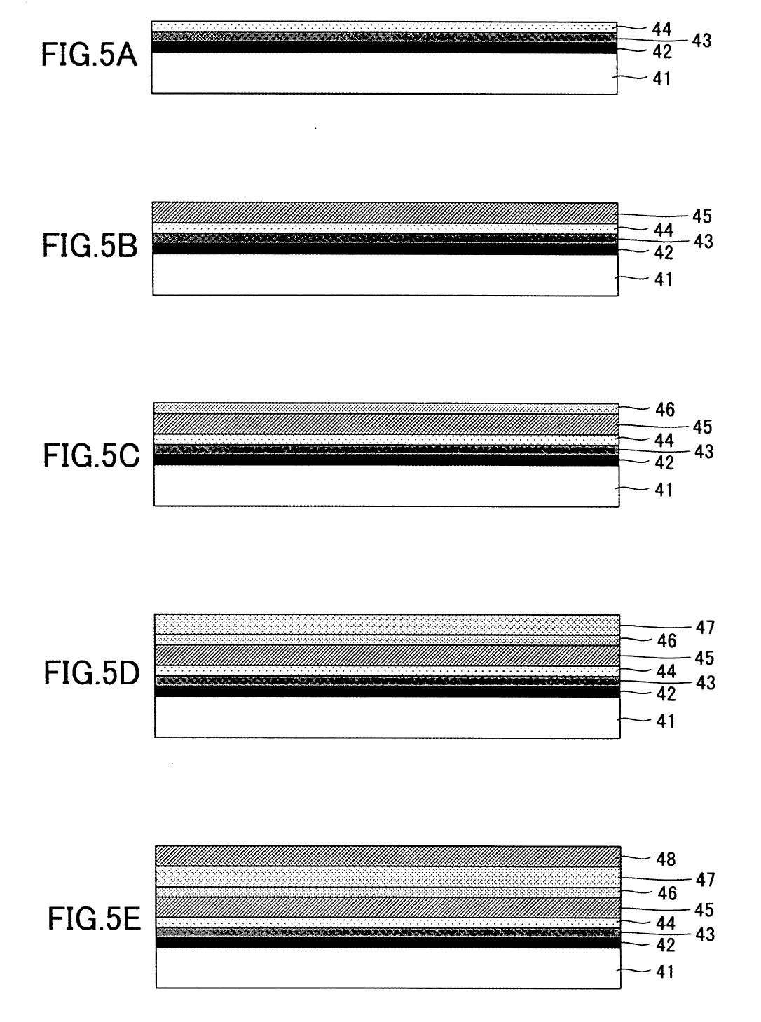

FIGS. 5A-5E show the fabrication process of a ferroelectric capacitor according to a first embodiment of the present invention.

Referring to FIG. 5A, there is formed a Ti film 42 having a (002) orientation on a silicon oxide film 42 covering a silicon substrate not illustrated by a sputtering process as an orientation control film, and a TiAlN film 43 is formed on the orientation control film 42 as a conductive oxygen diffusion barrier film by a reactive sputtering process. The silicon oxide film 41 may be the one that carries an Al₂O₃ film on a surface thereof.

For example, the Ti film 42 is formed in a DC sputtering apparatus in which the substrate to be processed is placed with a separation of 60 mm form the target in an Ar gas ambient of the pressure of 0.15 Pa while setting the substrate temperature to 20° C. and supplying a sputter power of 2.6 kW for 5 seconds. Further, the TiAlN film 43 is formed in the same DC sputtering apparatus with a thickness of 100 nm while using a target of an alloy of Ti and Al and an Ar/N₂ ambient of the pressure of 253.3 Pa, by supplying an Ar gas with a flow rate of 40 sccm and a nitrogen gas with a flow rate of 10 sccm, and setting the substrate temperature to 400° C. and supplying a sputter power of 1.0 kW.

Preferably, the Ti film 42 is nitrided once after the film formation thereof. By nitriding the Ti film 42 like this, it becomes possible to suppress the oxidation of Ti from the sidewall surface of the film at the time of the recovery annealing process of the ferroelectric film, which is conducted later.

Here, it should be noted that the conductive oxygen diffusion barrier film 43 is not limited to TiAlN but it is also possible to use an Ir film or a Ru film. Further, the orientation control film 42 is not limited to Ti or TiN and it is also possible to use any of Pt, Ir, Re, Ru, Pd, Os and an alloy thereof. Further, it is also possible to form the orientation control film 42 by a single-layer film or a laminated film of Ti, Al, Ir, Pt, Ru, Pd, Os, Rh, PtOx, IrOx, RuOx, PdOx, and the like.

With the step of FIG. 5A, there is further formed an Al₂O₃ film 44 on the TiAlN film 43 thus formed, with a thickness of 0.1 nm or more, preferably equal to or larger than 1 nm but not exceeding 5 nm, by a sputtering process or an ALD process.

In the case of forming the Al₂O₃ film 44 by a sputtering process, for example, an RF sputtering technology is used and the film formation is conducted at the substrate temperature of 10-100° C., such as 20° C. for example, in the Ar gas ambient in which the Ar flow rate is set to 10-50 sccm, such as 20 sccm for example, while using an alumina target and supplying the sputtering power of 0.2-4.0 kW. The Al₂O₃ film 44 thus formed functions as a diffusion barrier film of Pb and thus blocks the Pb atoms from reaching the TiAlN oxygen diffusion barrier film 43 by causing diffusion from the ferroelectric capacitor insulation film that contains Pb and causing reaction therein. As a result, the Al₂O₃ film 44 shows excellent adhesion to the TiAlN film 43.

Because the Al₂O₃ film 44 loses the function of Pb diffusion barrier when the thickness thereof has become smaller than 0.1 nm, it is preferable that the Al₂O₃ film 44 has a film thickness of 1 nm or more for constituting an effective Pb diffusion barrier film. Further, because the Al₂O₃ film is an insulation film, the tunneling efficiency of carriers is decreased when the thickness thereof has exceeded 5 nm, resulting in increase of resistance of the ferroelectric capacitor.

It should be noted that the Pb diffusion barrier film 44 is not limited to such an Al₂O₃ film, and thus an aluminum oxide film, but it is also possible to form the Pb diffusion barrier film 43 by any of a titanium oxide film, a zirconium oxide film, a hafnium oxide film, and a tantalum oxide film.

On the other hand, the Pb diffusion barrier film 44 may also be formed by a conductive metal oxide film. In this case, it is possible to use any of rhenium oxide rhodium oxide, osmium oxide, platinum oxide, iridium oxide, ruthenium oxide, vanadium oxide, neodymium oxide, europium oxide, samarium oxide, SrRuO₃, and LACO ((La,Sr)CoO₃) . In the case the Pb diffusion barrier film 44 is formed of a conductive metal oxide film, no limitation is imposed on the upper limit of the film thickness from the view point of tunneling of the carriers. However, from the viewpoint of throughput at the time of production, it is preferable to for the Pb diffusion barrier film 44 with the thickness of not exceeding 100 nm even in such a case. Further, with regard to the lower limit of the film thickness, it is necessary that the Pb diffusion barrier film has a film thickness of at least 0.1 nm similarly to the case of forming the Pb diffusion barrier film by an insulating metal oxide film. In order to obtain effective Pb barrier action, however, it is desirable that the Pb diffusion barrier film 43 has a thickness of 1 nm or more.

Further, it is possible to form the Al₂O₃ film by applying an oxidation processing to the surface of the TiAlN oxygen diffusion barrier film 43 by a rapid thermal annealing process conducted in an oxidizing ambient of 600-650° C. and cause formation of Al₂O₃ or TiOx. According to such a process, the Pb diffusion barrier film 44 is formed on the surface of the TiAlN oxygen diffusion barrier film 43 with a thickness of 3-5 nm.

Next, in the step of FIG. 5B, a lower electrode film 45 is formed on the Pb diffusion barrier film 44 in the form of a Pt film of the thickness of about 100 nm by as puttering process conducted in an Ar gas ambient of the pressure of 0.2 Pa, for example, at a substrate temperature of 400° C., while supplying a sputtering power of 0.5 kW. Here, it should be noted that the lower electrode 45 is not limited to pure Pt but may be formed of a noble metal alloy containing Pt or a laminated film in which a noble metal alloy containing Pt and platinum oxide (PtO) are laminated.

The Pt lower electrode film 45 thus formed has a (111) orientation and controls the orientation of the ferroelectric film formed thereon effectively in the (111) orientation.

Next, the structure of FIG. 5B is subjected to a rapid thermal annealing process conducted in an Ar gas ambient at the temperature of 650° C. for 60 seconds, wherein the Pt film 45 undergoes densification, and in the step of FIG. 5C, a first ferroelectric film 46 is formed on the lower electrode 45 by a sputtering process or a sol-gel process with a thickness of 1-50 nm, preferably 20-30 nm.

For the first ferroelectric film 46, it is possible to use a ferroelectric film having a ABO₃ perovskite structure in which the A side is occupied by at least one metal element selected from Bi, Pb, Ba, Sr, Ca, Na, K or a rare earth element and the B side is occupied by at least one element selected from Ti, Zr, Nb, Ta, W, Mn, Fe, Co and Cr, such as a PZT film. Further, for the first ferroelectric film 46, it is also possible to use, in place of the foregoing PZT film, a PZT film or PLZT film in which at least one of La, Ca, Sr and Si is doped, a BLT ((Bi,La)₄Ti₃O₁₂) film, and a Bi layered structure compound such as (Bi_{holes 1-x}Rₓ)Ti₃O₁₂ (R being a rare earth element, 0<x<1), SrBi₂Ta₂O₉, SrBi₄Ti₄O₁₅, or the like.

In the case of using a PZT film formed by a sputtering process for the ferroelectric film 46, it is preferable to add La, Ca, Sr, Nb, or the like, as mentioned previously, for improving the resistance to fatigue of the capacitor, improving the imprint characteristics, suppressing the leakage current and enabling low voltage driving. Thereby, it is preferable to set the concentrating of Ca to 5% in terms of mole ratio, the concentration of La to 2% in terms of mole ratio, and the concentration of Sr to 2% in terms of mole ratio, in view of the switching electric charge Q_{SW} of the ferroelectric capacitor.

Further, while not illustrated, it is possible to deposit a high-K dielectric such as zirconium oxide or lead oxide on the ferroelectric film 46.

Further, in the case of forming the ferroelectric film 46 by a sol-gel process, a sol-gel PZT solution is spin-coated on the lower electrode 45 to form a PZT coating film. Spin-coating of such a sol-gel PZT solution may be conducted by using a sol-gel solution of an organic solvent in which the precursors of the constituent elements of the desired PZT film are mixed with a predetermined ratio, such as a butanol solution of 10 weight percent. Thus, the sol-gel PZT solution may be spin-coated in the atmosphere of humidity of 40% at the room temperature by rotating the substrate to be processed with a rotational speed of 500 rpm for 30 seconds. For the sol-gel PZT solution, it is possible to use the one that contains Pb, La, Zr and Ti with a proportion of 1.10:2:40:60 (Pb:La:Zr:Ti=1.10:2:40:60). The PZT coating film thus formed is then annealed in an oxygen gas ambient of the ordinary pressure at a temperature not causing crystallization of PZT such as 200-450° C., 240° C. for example, and the solvent contained in the PZT film such as butanol is vaporized. As a result, there is formed a PZT film of amorphous phase or microcrystalline state on the lower electrode 45 in the step of FIG. 5C as the PZT film 46.

In the case the ferroelectric film 46 is a PZT film, the structure of FIG. 5C is annealed subsequently in an ambient containing oxygen such as a mixed gas ambient of an oxygen gas and an inert gas such as an Ar gas at the temperature of 550-800° C., such as 580° C., for 30-120 seconds, such as 90 seconds, while supplying the oxygen gas with the flow rate of 0-25 sccm and the Ar gas with the flow rate of 2000 sccm. With this, the PZT film 46 is crystallized.

In this crystallization thermal annealing process, the optimum anneal temperature depends on the material that constitutes the ferroelectric film m46. In the case of PZT, the optimum anneal temperature is 600° C. or less. In the case of using BLT, on the other hand, the optimum anneal temperature is preferably 700° C. or less. Further, in the case of using SBT, the optimum anneal temperature is preferably 800° C. or less.

By conducting such a crystallization thermal annealing process of the ferroelectric film 46 for the structure in which the lower electrode 45 is formed of Pt and the Pb diffusion barrier layer 44 is not provided, the Pb atoms in the film 46 penetrate through the lower electrode 45 by diffusion and reach the TiAlN oxygen diffusion barrier film 43 provided underneath the lower electrode 45. Thereby, there is caused cracking of the lower electrode film 45 as a result of the interface reaction as explained with reference to FIG. 4.

With the present invention, on the other hand, such a problem of cracking is successfully avoided by forming the Pb diffusion barrier film 44.

Next, in the step of FIG. 5D, a second ferroelectric film 47 is formed on the first ferroelectric film 46 by an MOCVD process.

More specifically, in the case of forming the second ferroelectric film 47 by a PZT film, Pb(DPM)₂, Zr(dmhd)₄ and Ti(O-iOr)₂(DPM)₂ are dissolved into a THF solvent respectively as the source of Pb, the source of Zr, and the source of Ti, with a concentration of 3 mole % for each, and the liquid source material thus obtained is supplied to a vaporizer of the MOCVD apparatus together with a THF solvent of the flow rate of 0.474 ml/minute, with the respective flow rates of 0.326 ml/minute, 0.200 ml/minute, and 0.200 ml/minute. With this, the source gases of Pb, Zr and Ti are formed.

Further, the source gas thus formed is introduced into the MOCVD apparatus and a PZT film 47 is formed on the lower electrode 71 with a thickness of 80 nm, for example, under the pressure of 665 Pa and the substrate temperature of 620° C.

Next, in the step of FIG. 5E, an upper electrode 48 is formed on the PZT film 47 by a sputtering process while using IrOx, which forms excellent interface to the PZT film. With the present embodiment, it should be noted that use of Pt, which shows catalytic action, in the upper electrode 48 is avoided, and with this, the problem of reduction of the PZT films 46 and 47 by activated hydrogen is suppressed.

More specifically, after the step of FIG. 5D, an IrOx film is formed on the PZT film 47 by a sputtering process at the substrate temperature of 300° C. with a thickness of 50 nm while supplying the Ar gas and the oxygen gas with respective flow rates of 120 sccm and 80 sccm and supplying the sputter power of 1-2 kW. The IrOx film thus formed with the thickness of 50 nm has a crystalline state at the time of the film deposition.

Next, the IrOx film thus formed is subjected to a rapid thermal annealing process at the temperature of 725° C. for 60 seconds while supplying the oxygen gas and the Ar gas with the respective flow rates of 20 sccm and 2000 sccm. With this, the IrOx film is completely crystallized. Further, with this rapid thermal annealing process, the oxygen defects formed in the PZT films 46 and 47 with formation of the upper electrode 48 are compensated.

Next, a second iridium oxide film (IrOy film) is formed on such a first iridium oxide film (IrOx film) thus formed by conducting a sputtering process in an Ar gas ambient with a thickness of 100-300 nm, such as 200 nm for example, while supplying a sputter power of 1.0 kW. The second iridium oxide film thus formed has a composition close to the stoichiometric composition of IrO2 and shows no catalytic action to hydrogen or water, contrary to Pt. Thus, even when a multilayer interconnection structure is formed on the structure of FIG. 5E, there is caused no problem of reduction of the PZT films 46 and 47 by hydrogen released from the water-containing interlayer insulation film, and the hydrogen resistance of the ferroelectric capacitor is improved.

By forming the upper electrode 48 in two-layer structure like this, excellent adhesion is secured between the lower IrOx film and the PZT film 47 further underneath, while the hydrogen resistance of the ferroelectric capacitor is improved by the upper IrOy film.

In the present embodiment, it is also possible to use Ir, Ru, Rh, Re, Os, Pd, and an oxide thereof or a conductive oxide such as SrRuO₃ for the upper electrode 48 in place of IrOx. Further, it is also possible to form the upper electrode 48 in the form of lamination structure of such metals or conductive oxides.

With the present embodiment, it is further possible to form an Ir film on the surface of the upper electrode 48, although not illustrated. With this, penetration of H₂O into the ferroelectric films 46 and 47 via the upper electrode 48 is suppressed, and at the same time, contact characteristics to an interconnection pattern are improved.

### Second Embodiment

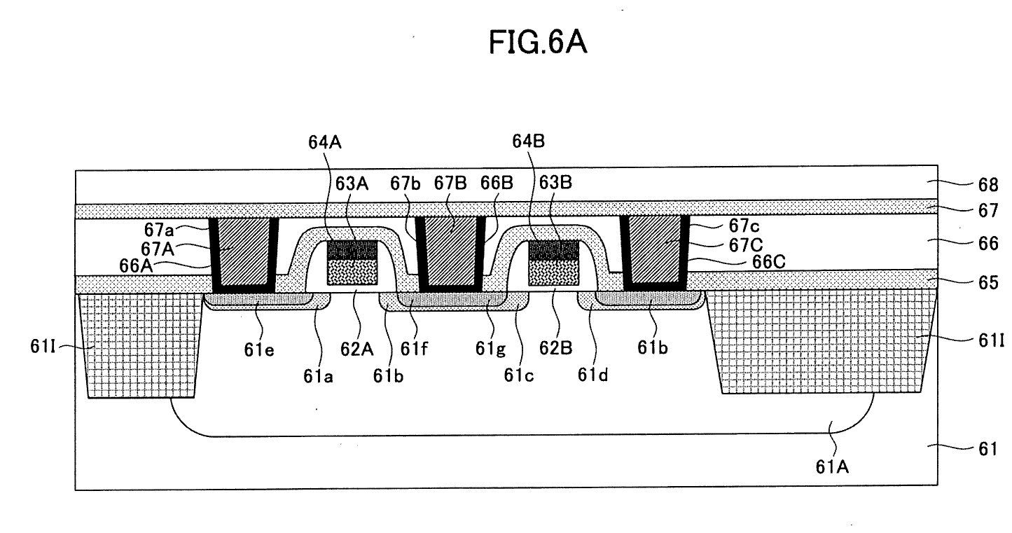

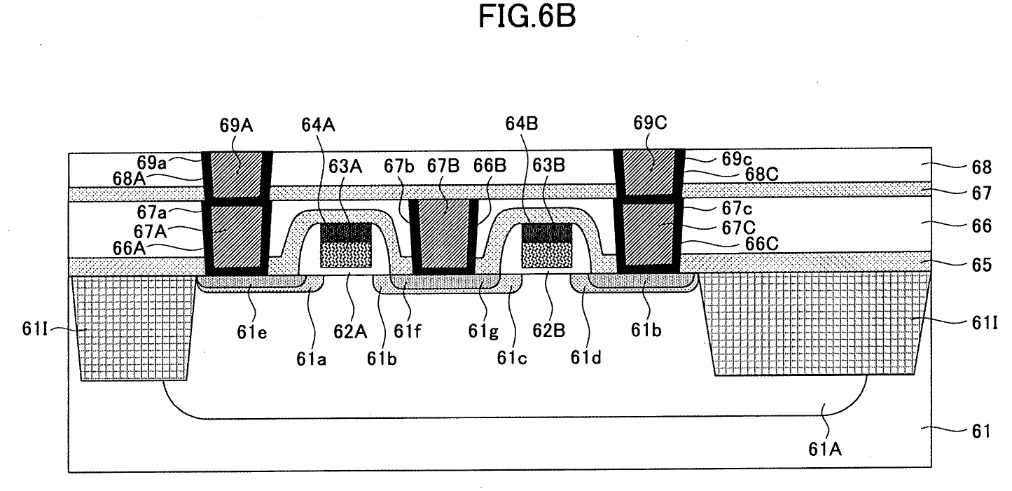

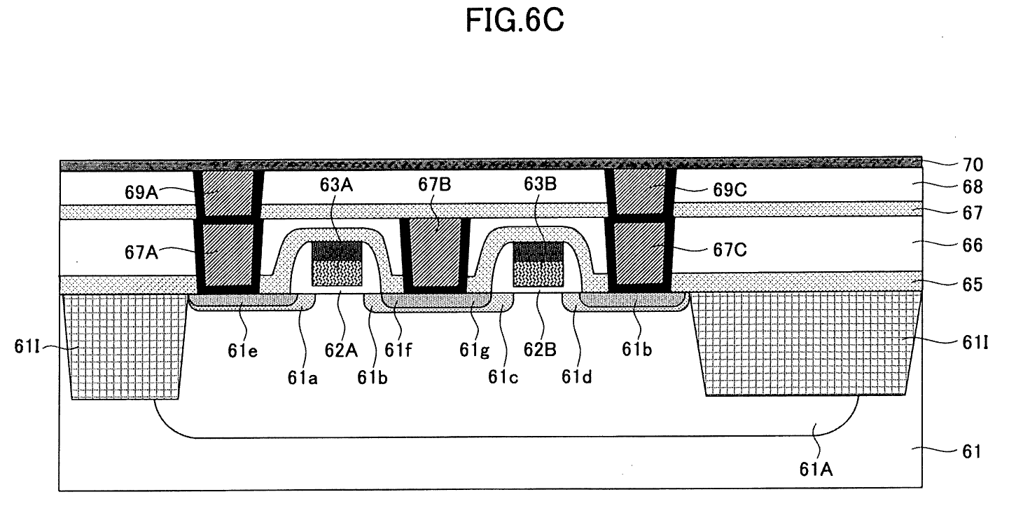

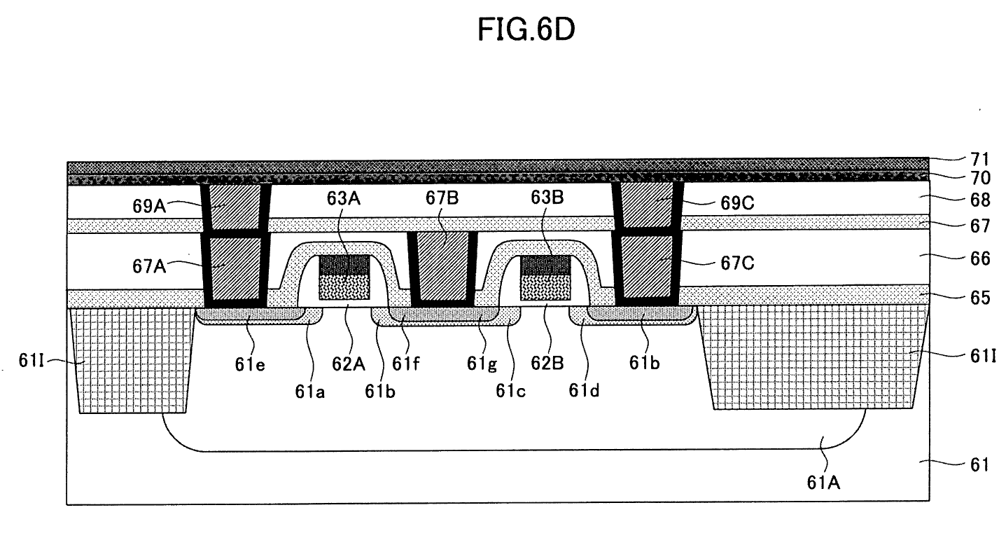

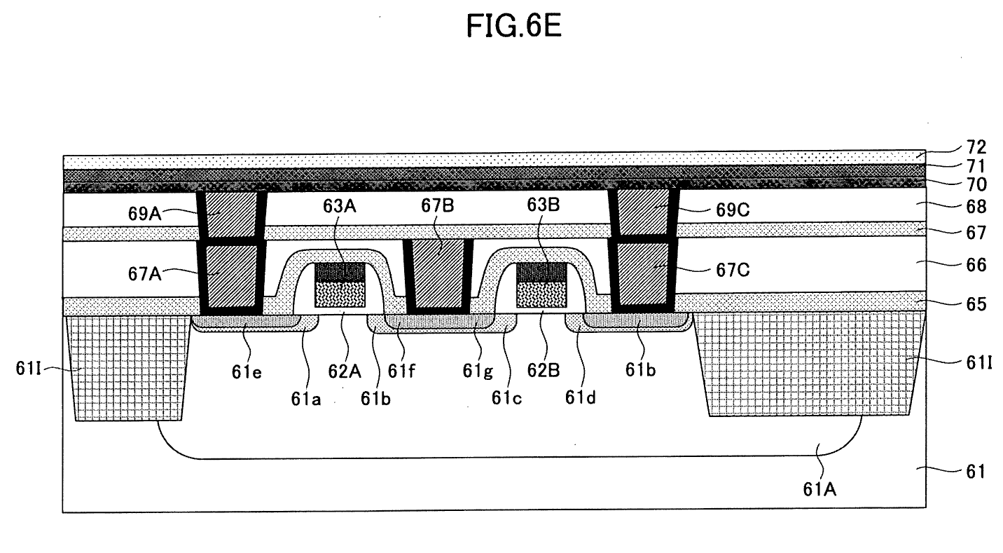

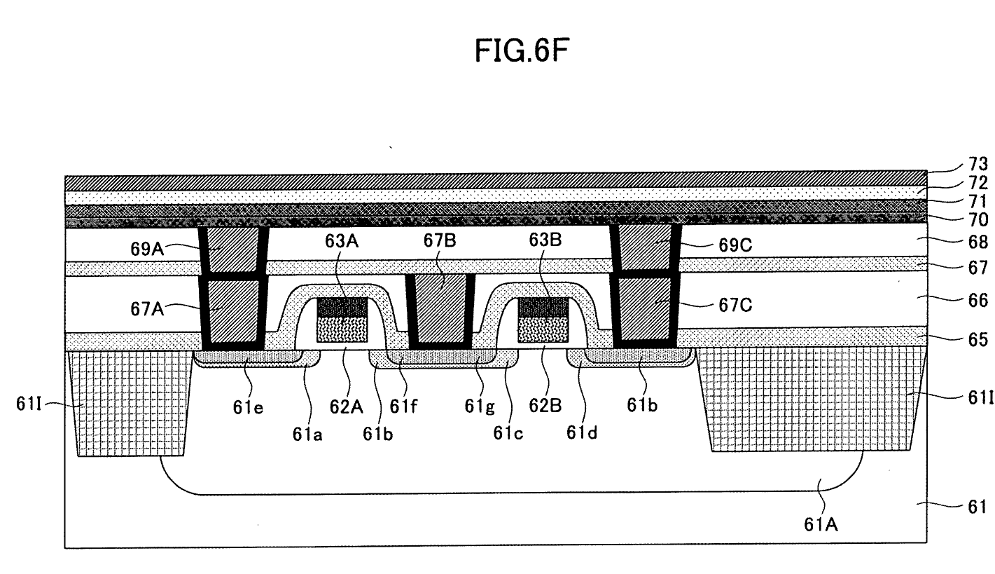

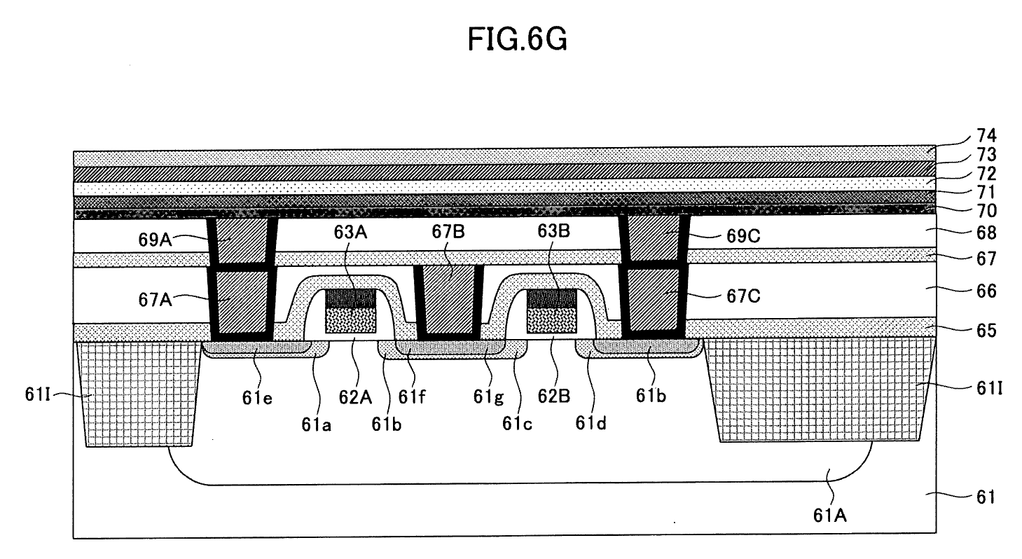

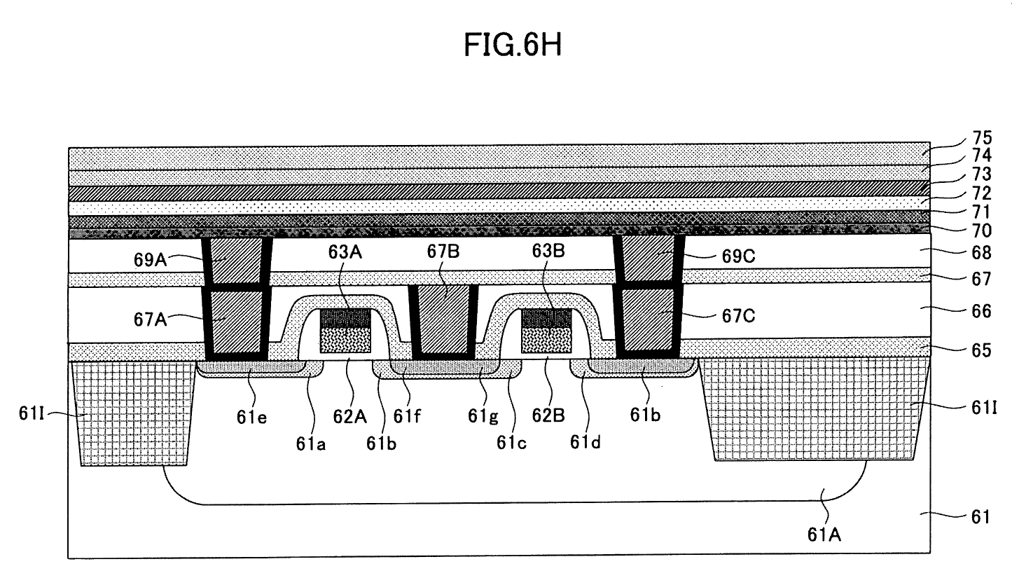

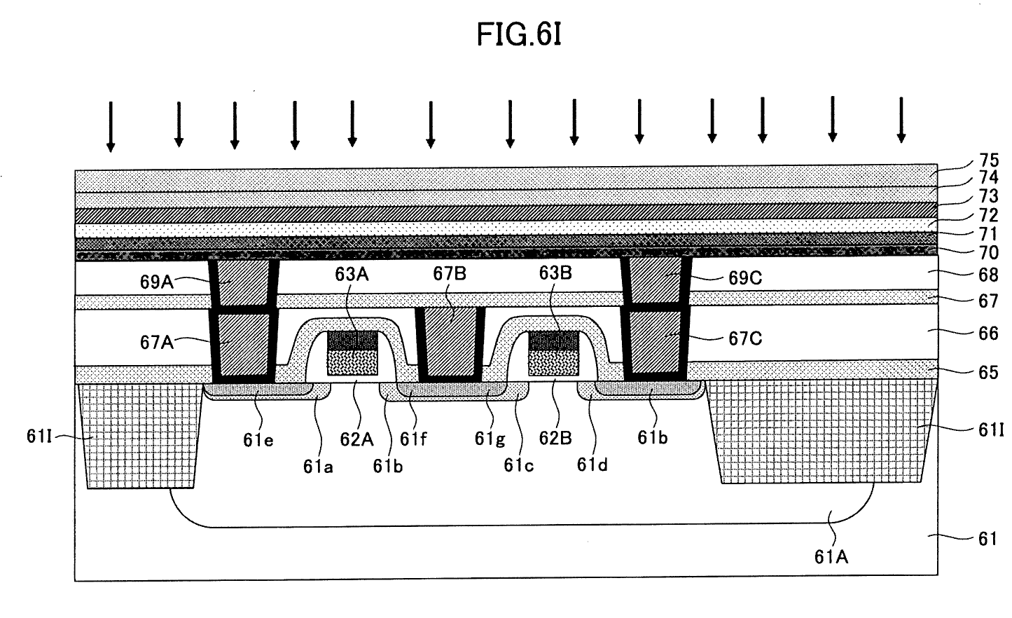

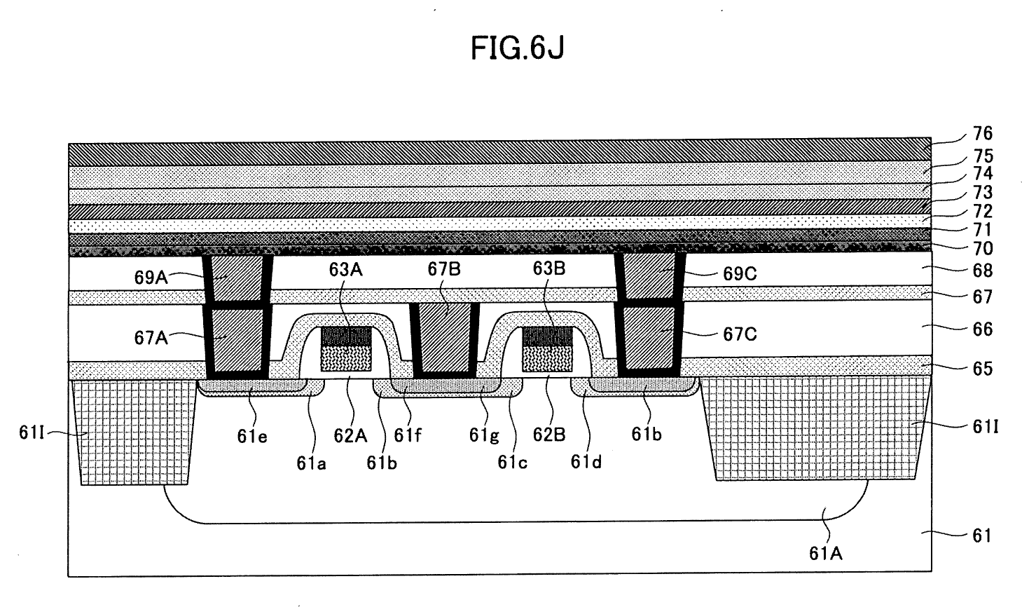

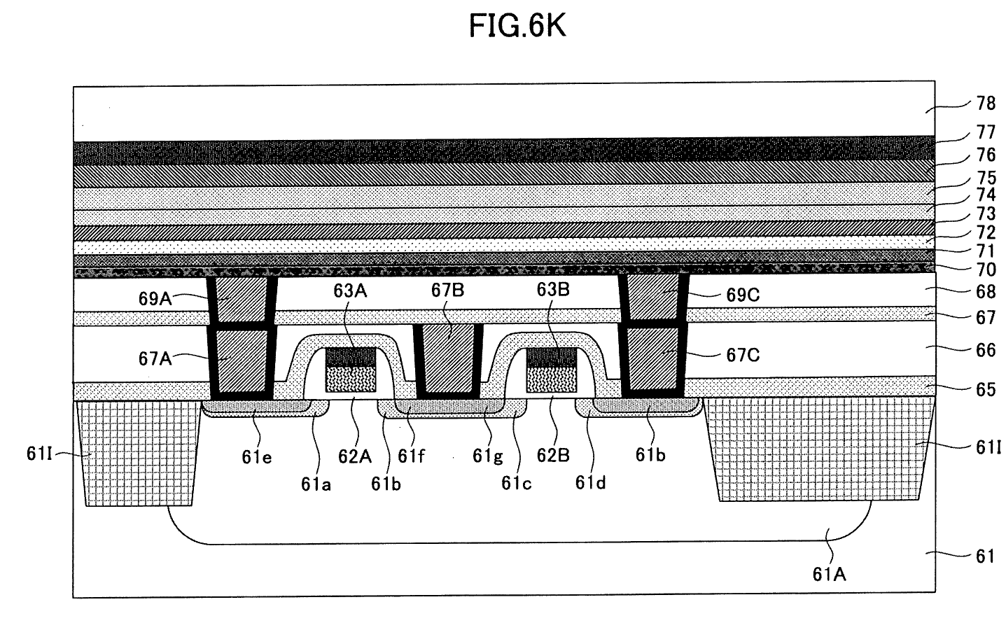

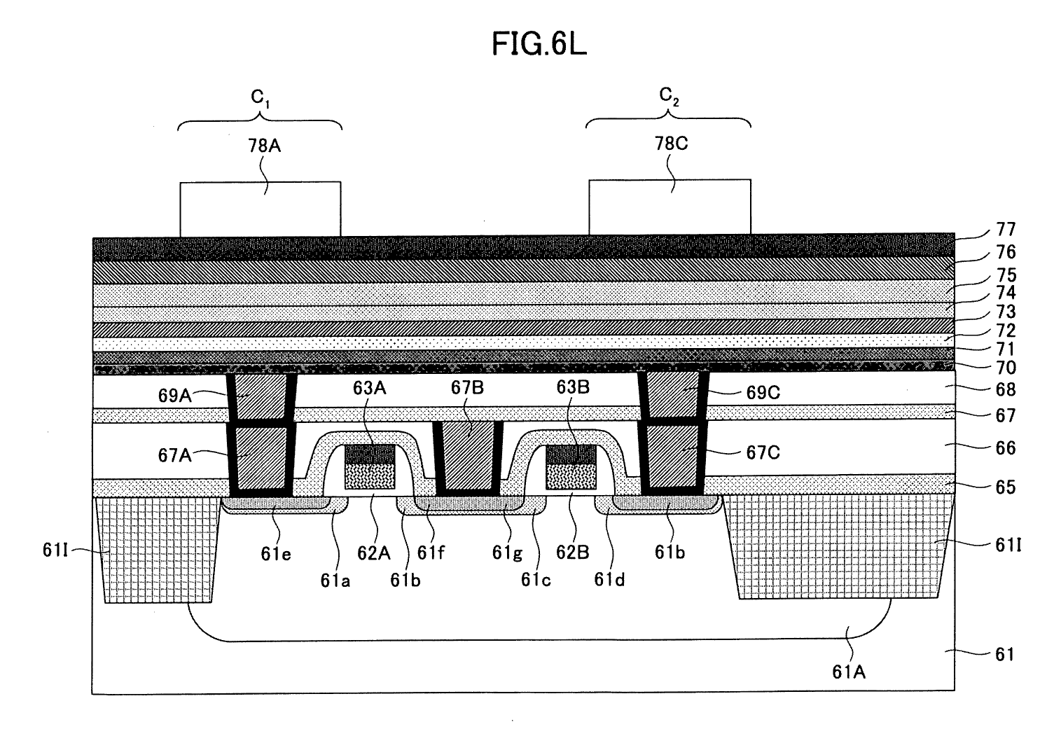

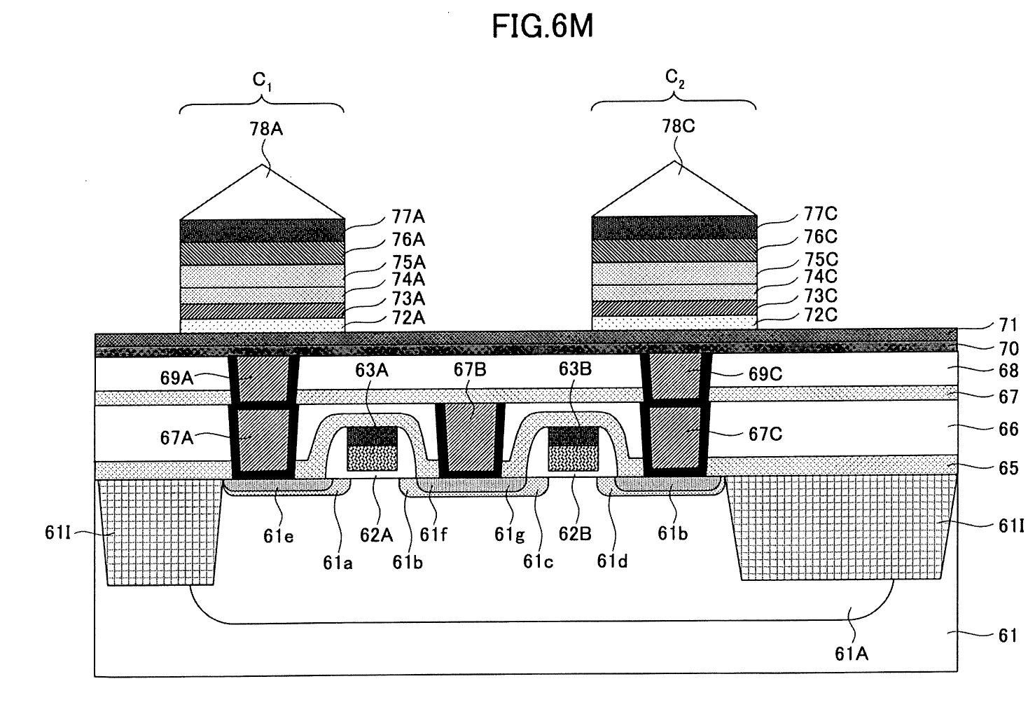

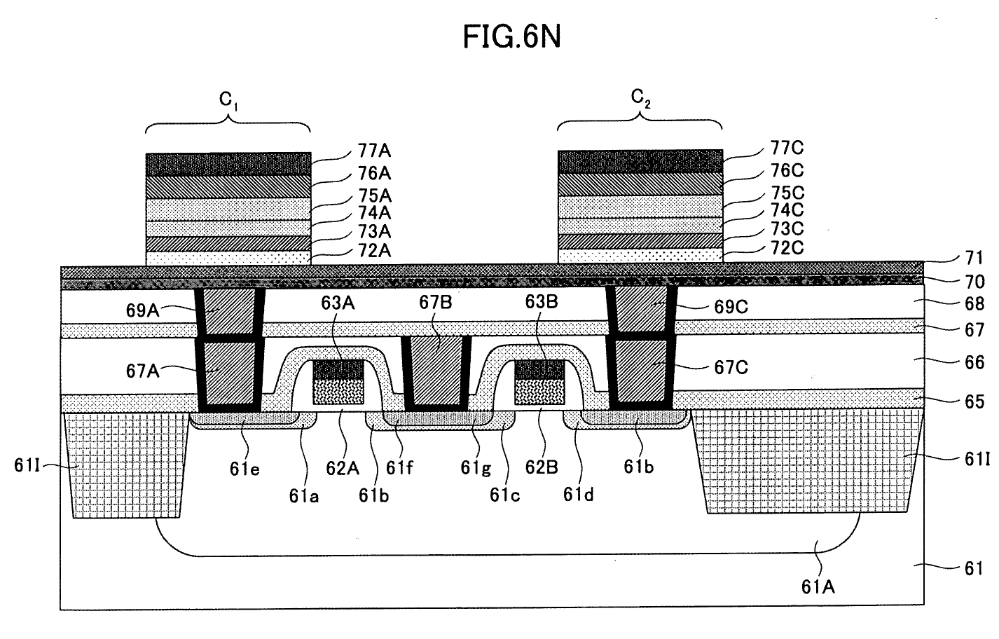

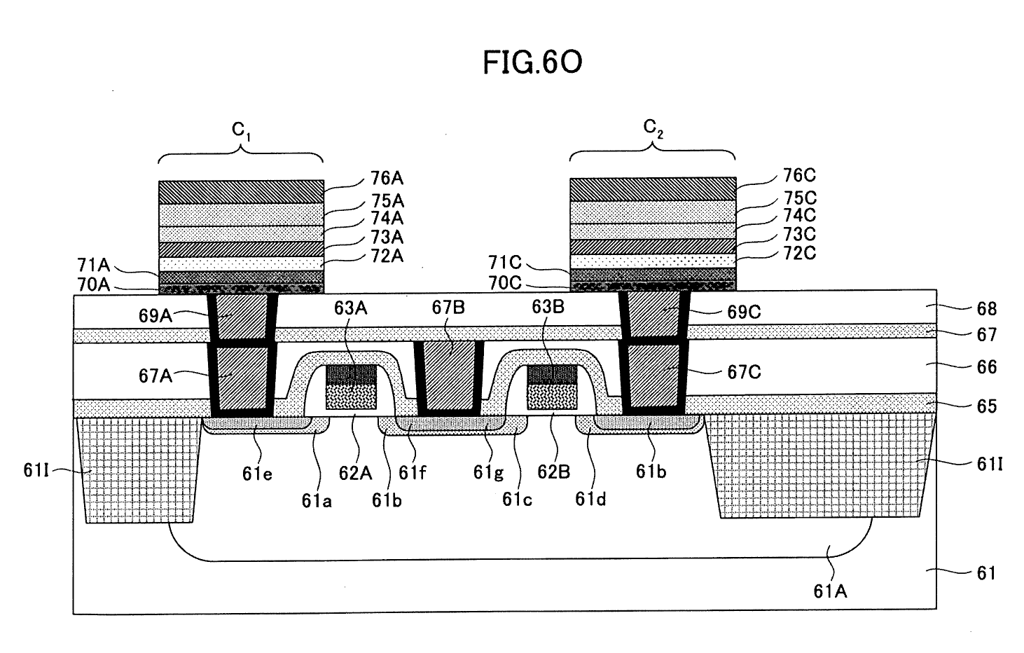

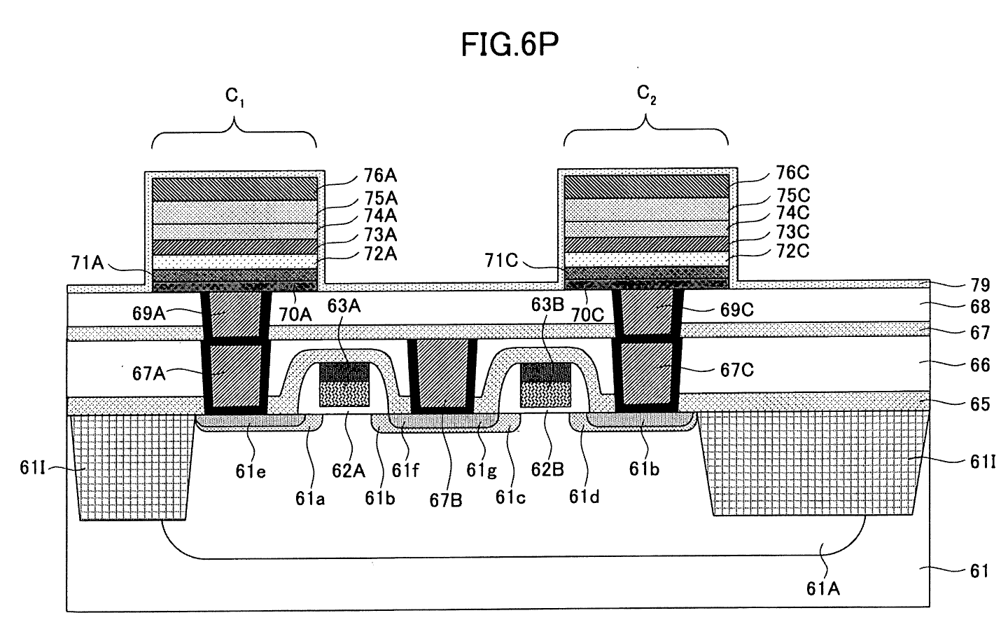

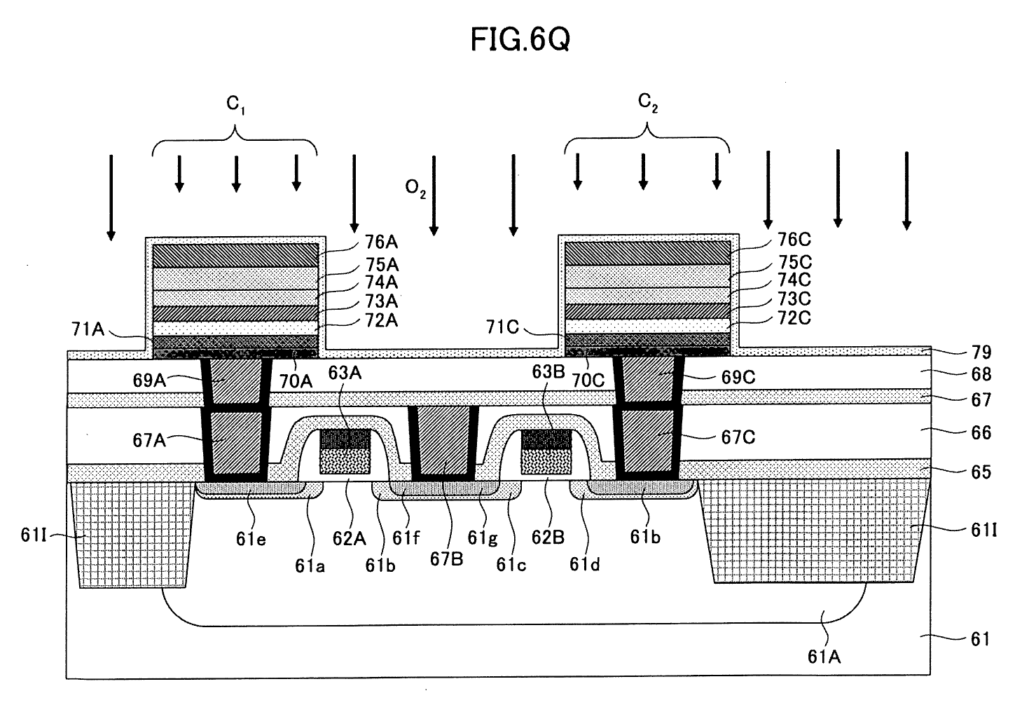

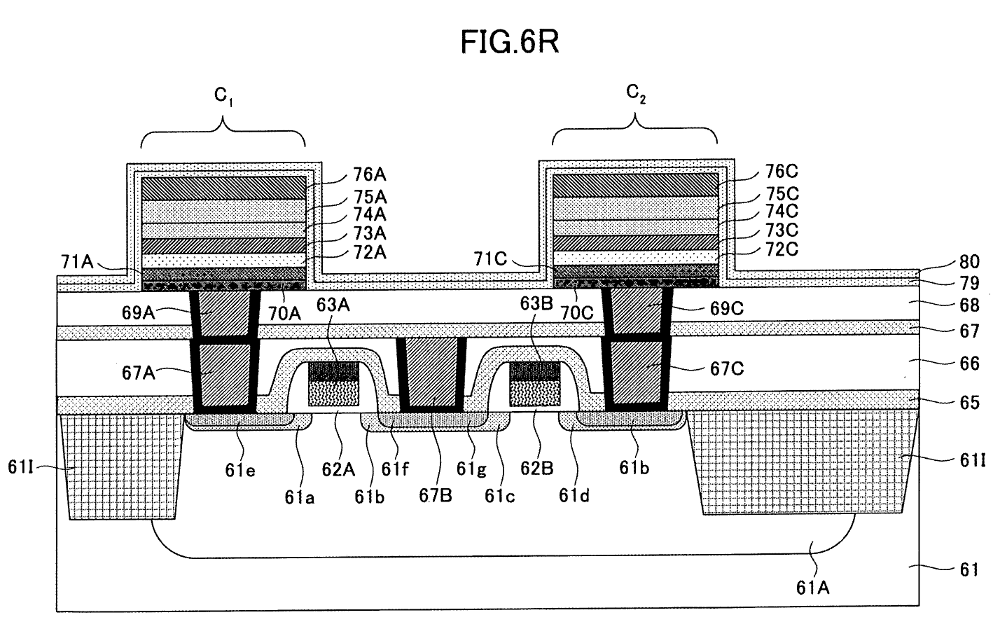

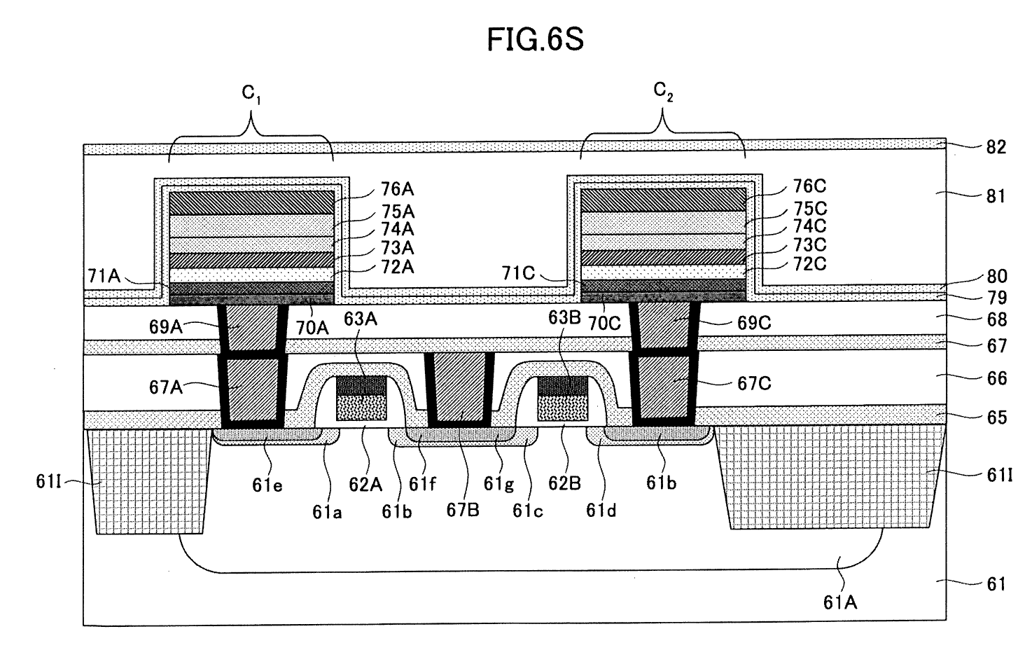

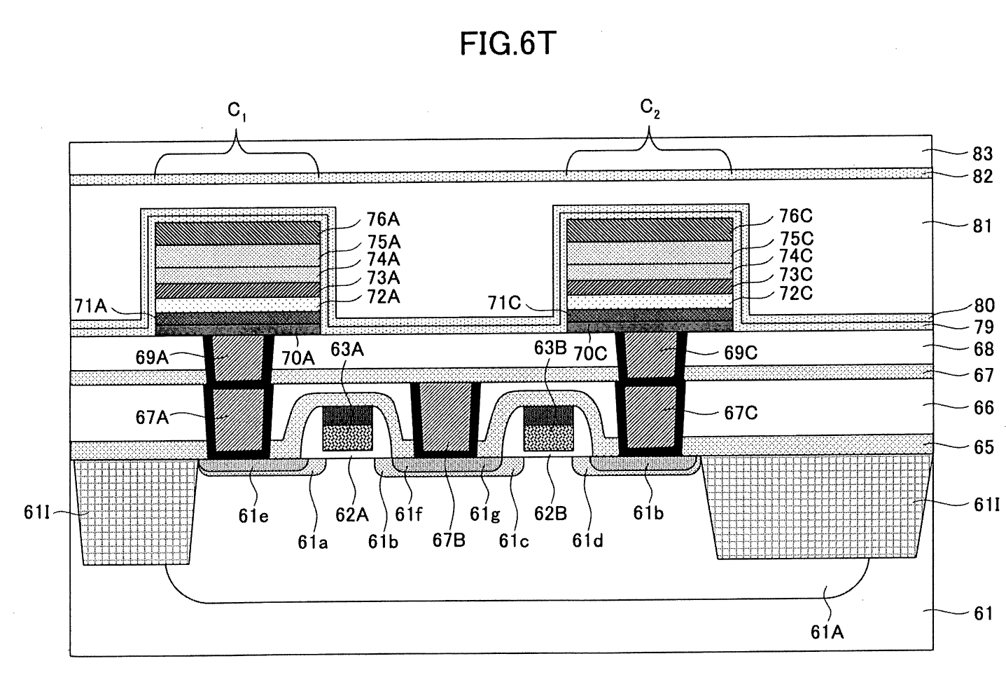

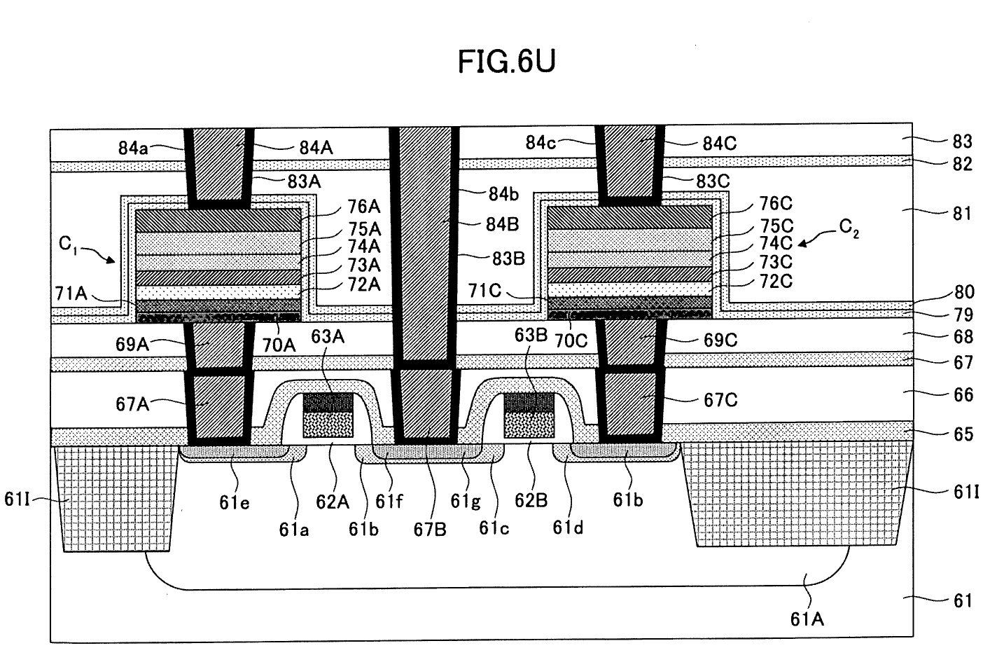

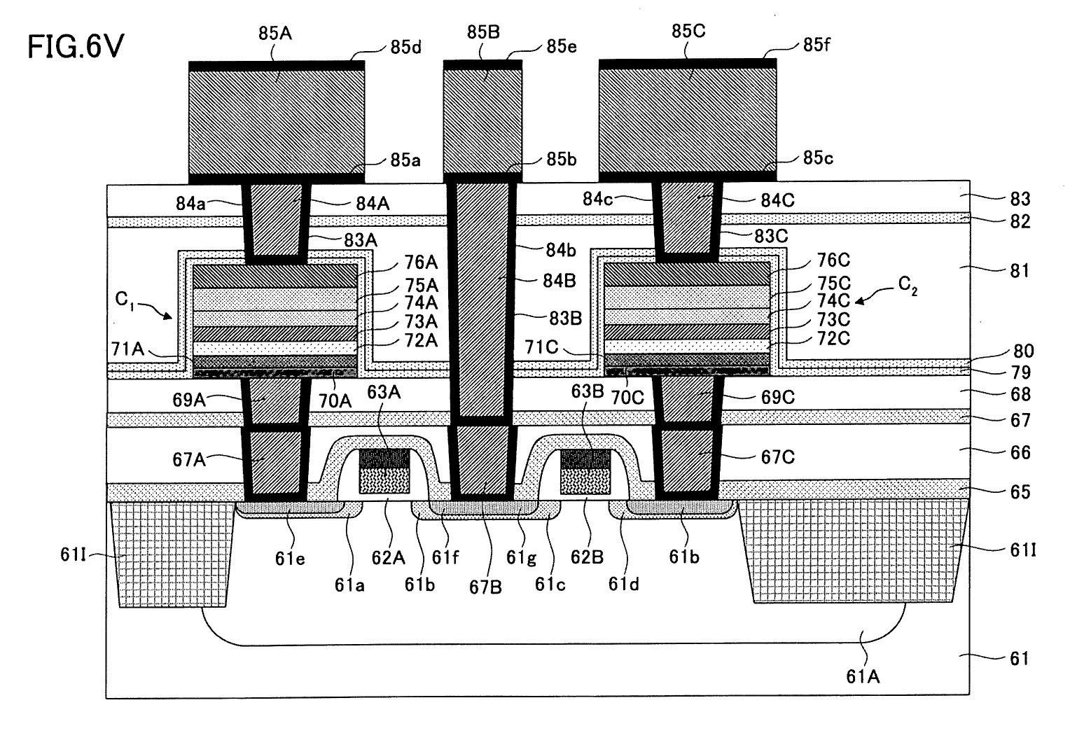

Hereinafter, the fabrication process of a ferroelectric memory according to a second embodiment of the present invention will be described with reference to FIGS. 6A-6V.

Referring to FIG. 6A, there is formed an n-type well in the silicon substrate 61 as a device region 61A, wherein there are formed, on the device region 61A, a first MOS transistor having a polysilicon gate electrode 63A and a second MOS transistor having a polysilicon gate electrode 63B via respective gate insulation films 62A and 62B.

Further, in the silicon substrate 61, there are formed LDD regions 61a and 61b of p⁻-type in correspondence to respective sidewalls of the gate electrode 63A, and there are further formed LDD regions 61c and 61d of p⁻-type in correspondence to respective sidewalls of the gate electrode 63B. Thereby, the first and second MOS transistors are formed commonly in the device region 61A, and thus, the same p-type diffusion region is used as the LDD region 61b and the LDD region 61c.

On the polysilicon gate electrodes 63A and 63B, there are formed silicide layers 64A and 64B, respectively, and there are further formed sidewall insulation films on the sidewall surfaces of the polysilicon gate electrode 63A and on the sidewall surfaces of the polysilicon gate electrode 63B, respectively.

Furthermore, diffusion regions 61e and 61f of p⁺-type are formed in the silicon substrate 61 at respective outer sides of the sidewall insulation films of the gate electrode 63A, and diffusion regions 61g and 61h of p⁺-type are formed in the silicon substrate 61 at respective outer sides of the sidewall insulation films of the gate electrode 63B. Thereby, the diffusion regions 61f and 61g are formed by the same p⁺-type diffusion region.

Further, on the silicon substrate 61, there is formed an SiON film 65 so as to cover the gate electrode 63A including the silicide layer 64A and the sidewall insulation films of the gate electrode 63A and so as to cover the gate electrode 63B including the silicide layer 64B and the sidewall insulation films on the gate electrode 63B, and an interlayer insulation film 66 of SiO₂ is formed on the SiON film 65 by a plasma CVD process that uses TEOS for the source material with a thickness of 100 nm, for example. Further, the interlayer insulation film 66 is planarized by a CMP process, and contact holes 66A, 66B and 66C are formed in the interlayer insulation film 66 so as to expose the diffusion regions 61e, 61f (and thus the diffusion region 61g) and 61h, respectively. In the contact holes 66A, 66B and 66C, there are formed via plugs 67A, 67B and 67C respectively via respective adhesion layers 67a, 67b and 67c, wherein each adhesion layer is formed of lamination of a Ti film of the thickness of 30 nm and a TiN film of the thickness of 20 nm.

Further, with the structure of FIG. 6A, it should be noted that there is formed a next interlayer insulation film 68 of a silicon oxide film on the interlayer insulation film 66 with a thickness of 300 nm, for example, via another SiON film 67 of the thickness of 130 nm for example, by a plasma CVD process that uses TEOS for the source material similarly to the interlayer insulation film 66. Again, it is possible to use an SiN film or Al₂O₃ film in place of the SiON film 67.

Next, in the step of FIG. 6B, via holes 68A and 68C are formed in the interlayer insulation film 68 for exposing the via-plugs 67A and 67C, and a via-plug 69A of tungsten is formed in the via-hole 68A so as to make a contact with the via-plug 67A via an adhesion layer 69a in which a Ti film and a TiN film are laminated similarly to the adhesion film 67a. Further, in the via-hole 68C, there is formed a via-plug 69C of tungsten in contact with the via-plug 67C via an adhesion layer 69c in which a Ti film and a TiN film are laminated similarly to the case of the adhesion film 67c.

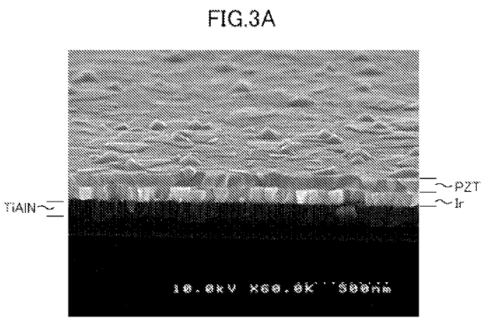

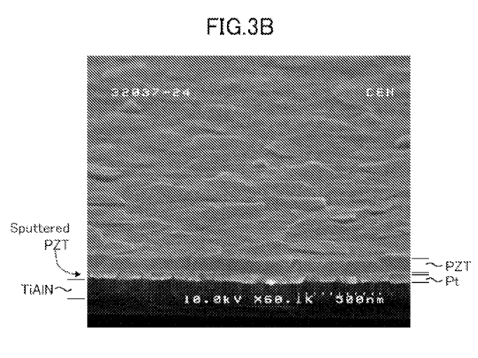

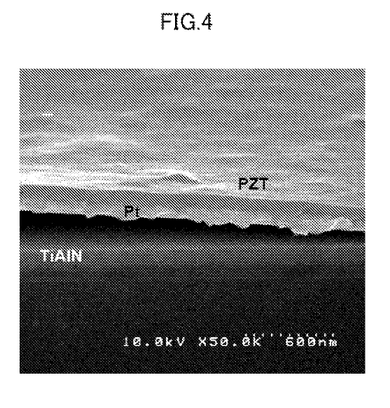

Next, in the step of FIG. 6C, the surface of the interlayer insulation film 68 is processed with NH₃ plasma such that NH groups cause bonding with the oxygen atoms at the surface of the interlayer insulation film 68. Next, a Ti film 70 is formed on the interlayer insulation film 68 by a sputtering process with a thickness of 20 nm, for example, under the similar condition to the case of forming the Ti film 42 of FIG. 3A, such that the Ti film 70 covers the via-plugs 69A and 69B. By processing the surface of the interlayer insulation film 68 with such NH₃ plasma, the oxygen atoms at the surface of the interlayer insulation film 68 are terminated by the NH groups, and thus, the Ti atoms deposited on the interlayer insulation film experiences no orientation control of the oxygen atoms. Thus, the Ti layer 70 shows an ideal (002) orientation.

Further, with the step of FIG. 6C, the Ti film 70 is subjected to a rapid thermal annealing process in a nitrogen gas ambient at the temperature of 650° C., and the Ti film 70 is converted to a TiN film 70 of a (111) orientation.

Next, in the step of FIG. 6D, a TiAlN film 71 is formed on the TiN film 70 as an oxygen barrier film under the condition similar to the TiAlN film 43 of FIG. 5A, and an Al₂O₃ film 72 is formed on the TiAlN film 71 as a Pb diffusion barrier film similarly to the Al₂O₃ film 44 of the step of FIG. 5A.

Next, in the step of FIG. 6F, a Pt film is deposited on the Al₂O₃ film 72 by a sputtering process similarly to the lower electrode 45 of FIG. 5B with a thickness of about 100 nm, and with this, a lower electrode layer 73 is formed.

Next, the structure of FIG. 6F is subjected to a thermal annealing process for 60 seconds in an Ar gas ambient similarly to the previous embodiment at the temperature of 650° C. or higher, and the step of FIG. 6G is conducted subsequently, wherein a first PZT film 74 is formed on the lower electrode layer 73 by a sputtering process with a thickness of 1-50 nm, preferably 20-30 nm, similarly to the PZT film 46 of FIG. 5C.

Next, in the step of FIG. 6H, a second PZT film 75 is formed on the PZT film 74 by an MOCVD process with a thickness of 80 nm, for example, similarly to the ferroelectric film 47 of the step of FIG. 5D.

Further, in the step of FIG. 6I, the PZT films 74 and 75 are annealed in an ambient containing oxygen such as a mixed gas ambient of an oxygen gas and an inert gas such as an Ar gas at the temperature of 550-800° C., such as 580° C., for 30-120 seconds, such as 90 seconds, while supplying the oxygen gas with the flow rate of 0-25 sccm and the Ar gas with the flow rate of 2000 sccm. With this, the PZT film 46 is crystallized. As a result of crystallization of the PZT film 73, there is caused growth of columnar PZT crystals of (111) orientation in the PZT films 74 and 75 in the upward direction from the surface of the lower electrode 73.

Next, in the step of FIG. 6H, an upper electrode film 76 is formed on the PZT film 74 by a sputtering process similarly to the upper electrode layer 48 shown in FIG. 5E of the previous embodiment, and a TiAlN film 77 and a silicon oxide film 78 are formed on the upper electrode film 76 in the step of FIG. 6K respectively by a reactive sputtering process and a plasma CVD process that uses a TEOS source material as a hard mask layer.

Further, in the step of FIG. 6L, the silicon oxide film 78 and the TiAlN film 77 underneath the silicon oxide film 78 are patterned, and hard mask patterns 78A and 78B are formed respectively in correspondence to the desired ferroelectric capacitors C1 and C2.

Further, with the step of FIG. 6M, the TiAlN film 77, the upper electrode layer 76, the PZT films 74 and 75, the lower electrode layer 73 and the Al₂O₃ film are patterned by a dry etching process that uses HBr, O₂, Ar and C₄F₈ while using the hard mask patterns 78A and 78B as a mask, until the TiAlN film 71 is exposed. With this, there is formed a structure, in which an Al₂O₃ pattern 72A, a lower electrode pattern 73A, PZT patterns 74A and 75A, and a TiAlN mask pattern 77A are laminated, under the hard mask pattern 78A in correspondence to the ferroelectric capacitor C1. Further, there is formed a structure, in which an Al₂O₃ pattern 72C, a lower electrode pattern 73C, PZT patterns 74C and 75C, and a TiAlN mask pattern 77AC are laminated, under the hard mask pattern 78C in correspondence to the ferroelectric capacitor C2. Here, it should be noted that the lower electrode pattern 73A, the PZT patterns 74A and 75A and the upper electrode pattern 76A constitute the ferroelectric capacitor C1, while the lower electrode pattern 73C, the PZT patterns 74C and 75C and the upper electrode pattern 76C constitute the ferroelectric capacitor C2.

Next, in the step of FIG. 6N, the hard mask patterns 78A and 78C are removed by a dry etching process or wet etching process, and the TiN film 70 on the interlayer insulation film 68 and the TiAlN film 71N thereon are removed by a dry etching process while using the ferroelectric capacitors C1 and C2 as a mask in the step of FIG. 60. With this there is formed a structure for the capacitor C1 in which a TiN pattern 70A and a TiAlN pattern 71A are laminated underneath the Al₂O₃ pattern 72A and there is formed a structure for the capacitor c2 in which a TiN pattern 70C and a TiAlN pattern 71C are laminated underneath the Al₂O₃ pattern 72C.

Further, in the step of FIG. 6P, there is formed an extremely thin Al₂O₃ film 79 of the thickness of 20 nm or less on the interlayer insulation film 69 exposed in the step of FIG. 60 as a hydrogen barrier film such that the Al₂O₃ film covers the sidewall surfaces and the top surfaces of the ferroelectric capacitors C1 and C2 continuously by a sputtering process or ALD process, and in the next step of FIG. 6Q, a thermal annealing process is conducted in an oxygen gas ambient at the temperature of 550-750° C., such as 650° C. With this, the damaging caused in the dry etching process of FIG. 60 is recovered in they PZT films 74A and 75A and 74C and 75C of the ferroelectric capacitors C1 and C2.

Further, in the step of FIG. 6R, a next Al₂O₃ film 80 is formed on the Al₂O₃ film 79 of FIG. 6P also as a hydrogen barrier film by an MOCVD process with a thickness of 20 nm, for example, and an interlayer insulation film 81 of a silicon oxide film is formed so as to cover the Al₂O₃ hydrogen barrier films 79 and 80 thus formed, by a plasma CVD process that uses a mixed gas of TEOS and oxygen and helium for the source material with a thickness of 1500 nm. In the step of FIG. 6S, the surface of the interlayer insulation film 81 thus formed is planarized by a CMP process, and water in the interlayer insulation film 81 is removed by conducting annealing process in the plasma that uses N₂O or nitrogen gas. Further, in the step of FIG. 6S, an Al₂O₃ film 82 is formed on the interlayer insulation film 81 as a hydrogen barrier film with a thickness of 20-100 nm by a sputtering process or MOCVD process. In the step of FIG. 6S, it should be noted that the interlayer insulation film 81 has a thickness of 700 nm as a result of planarization by the CMP process.

Next, in the step of FIG. 6T, an interlayer insulation film 83 of a silicon oxide film is formed on the hydrogen barrier film 82 by a plasma CVD process that uses the TEOS source material with the thickness of 30-500 nm, and in the step of FIG. 6U, there are formed via-holes 83A and 83C in the interlayer insulation film 83 respectively exposing the upper electrode 76A of the ferroelectric capacitor C1 and the upper electrode 76C of the ferroelectric capacitor C2.

Further, in the step of FIG. 6U, a thermal annealing process is conducted in an oxidizing ambient through the via-holes 83A and 83C thus formed, and the oxygen defects formed in the PZT films 74A, 75A, 74C and 75C with the via-hole formation process are compensated.

Next, the bottom surfaces and inner wall surfaces of the via-holes 83A and 83C are covered by barrier metal films 84a and 84c of a TiN single layer film, and the via-holes 83A and 83C are filled respectively with the tungsten plugs 84A and 84C.

Further, after formation of the tungsten plugs 84A and 84C, there is formed a via-hole 83B in the interlayer insulation film 83 exposing the via-plug 67B and the via-hole 83B is filled with a tungsten via-plug 84B. As usual, the tungsten via-plug 84B is accompanied with an adhesion film 84b of the Ti/TiN laminated structure.

Further, in the step of FIG. 6V, an interconnection pattern 85A of an AlCu alloy is formed on the interlayer insulation film 83 in correspondence to the via-plug 84A in the form sandwiched by adhesion films 85a and 85d of the Ti/TiN lamination structure. Similarly, an interconnection pattern 85B of an AlCu alloy is formed on the interlayer insulation film 83 in correspondence to the via-plug 84B in the form sandwiched by adhesion films 85b and 85e of the Ti/TiN lamination structure. Further, an interconnection pattern 85C of an AlCu alloy is formed on the interlayer insulation film 83 in correspondence to the via-plug 84C in the form sandwiched by adhesion films 85c and 85f of the Ti/TiN lamination structure.

Further, a further interconnection layer may be provided on the structure of FIG. 6V according to the needs.

With the ferroelectric memory thus formed, the PZT film constituting the ferroelectric capacitors C1 and C2 are formed of columnar PZT crystals of uniform (111) orientation as a result of use of the Pt electrode, and excellent electric characteristics are obtained as explained previously with reference to FIGS. 5A and 5B. Further, because there are formed Pb diffusion barrier layers 22A and 22C of Al₂O₃, or the like, between the Pt lower electrode and the conductive oxygen diffusion barrier layer containing Ti, Al and N provided underneath the Pt lower electrode, the problem of cracking of the lower electrode caused by the diffusion of the Pb atoms from the PZT film to the conductive oxygen diffusion barrier film is eliminated. IN the case of constituting the Pb diffusion barrier layers 22A and 22C by an insulation material such as Al₂O₃, it is preferable that the Pb diffusion barrier layers 22A and 22B have a thickness of 5 nm or less in view of difficulty of carrier tunneling in the case the film thickness exceeds 5 nm. On the other hand, with regard to the lower limit of the Pb diffusion barrier layers 22A and 22C, it is necessary that the Pb diffusion barrier layers 22A and 22C have a minimum thickness of 0.1 nm. In the case the film thickness is excessively small, the function of Pb diffusion barrier does not develop. Thus, it is preferable that the Pb diffusion barrier films 22A and 22C are formed with a thickness of 1 nm or more.

For the conductive diffusion barrier films 22A and 22C, it is also possible to use other insulating metal oxide film such as titanium oxide film, zirconium oxide film, hafnium oxide film, tantalum oxide film, or the like in place of the Al₂O₃ film and thus aluminum oxide film, similarly to the previous embodiment.

Further, in the case of forming the conductive diffusion barrier films 22A and 22C by a conductive metal oxide film, it is necessary to provide the film with the thickness of at least 0.1 nm. In order to obtain the effective function of Pb diffusion barrier, it is preferable to form the diffusion barrier films 22A and 22C also with the film thickness of 1 nm or more. For such a conductive metal oxide, it is possible to use any of rhenium oxide rhodium oxide, osmium oxide, platinum oxide, iridium oxide, ruthenium oxide, vanadium oxide, neodymium oxide, europium oxide, samarium oxide, SrRuO₃, and (La,Sr)CoO₃.

Further, while the present embodiment has been explained for the case the ferroelectric films 74A and 75A or 74C and 75C are formed of PZT films, it should be noted that the PZT film that form the lower ferroelectric films 74A and 74C may contain an element such as Ca or Sr in the event the lower ferroelectric films 74A and 74C are formed by a sputtering process as explained previously. Further, the PZT films 74A, 75A, 74C and 75C may be a PLZT film containing La.

Further, the ferroelectric films 74A, 75A, 74C and 75C are not limited to a PZT film but may be formed by any of a ferroelectric film containing Pb and having the ABO₃ perovskite structure. For example, the metal element occupying the A site may be any of Bi, Pb, Ba, Sr, Ca, Na, K, or the like, and a rare earth element, while the metal element occupying the B side may be any of Ti, Zr, Nb, Ta, W, Mn, Fe, Co, Cr, and the like.

Further, the lower electrodes 73A and 73C are not limited to Pt film but may be formed by an alloy containing Pt. Further, the lower electrodes 73A and 73C may be formed by a lamination of platinum oxide (PtO) and Pt or an alloy containing Pt.

Further, it should be noted that the conductive oxygen diffusion barrier films 71A and 71C are not limited to TiAlN but it is also possible to use an Ir film or a Ru film.

Further, the orientation control films 70A and 70C are not limited to a Ti film or TiN film but may be formed of any of a Pt film, an Ir film, a Re film, a Ru film, a Pd film, an Os film, or an alloy of the elements constituting these films. Further, it is also possible to form the orientation control films 70A and 70C by a single-layer film or a laminated film of any of Ti, Al, Ir, Pt, Ru, Pd, Os, Rh, PtOx, IrOx, RuOx, PdOx, and the like.

### Third Embodiment

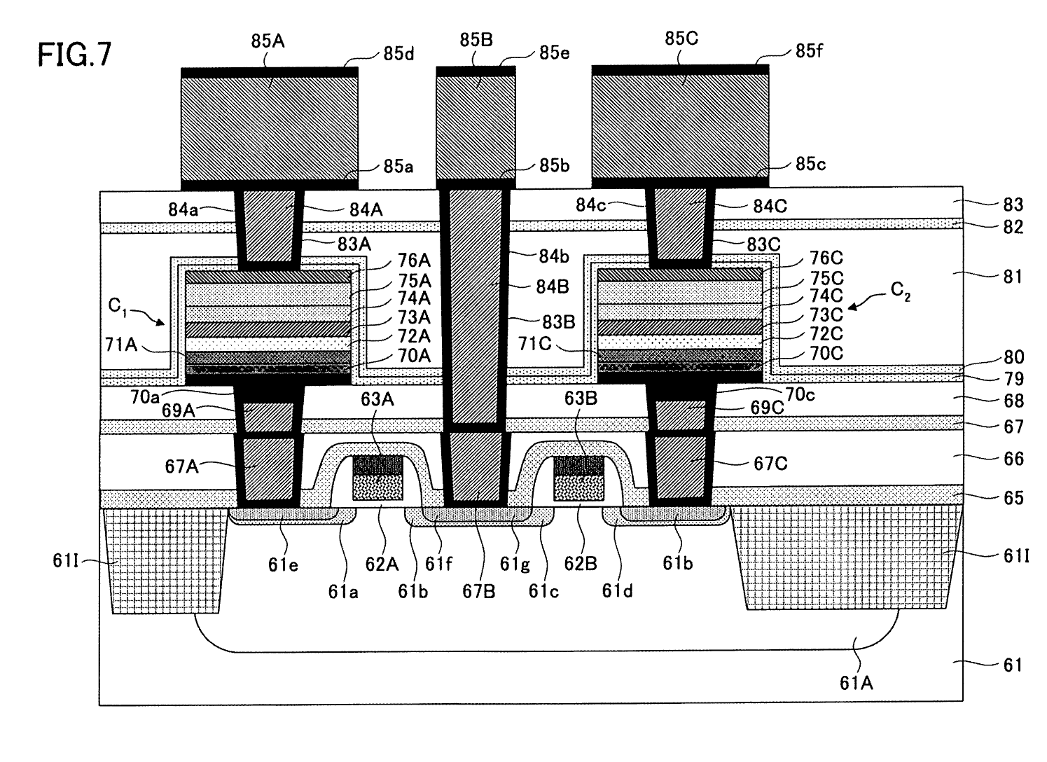

FIG. 7 shows the construction of a ferroelectric memory according to a third embodiment of the present invention. In the drawing, those parts explained previously are designated by the same reference numerals and the description thereof will be omitted.

With the embodiment explained before with reference to FIGS. 6A-6V, formation of the via-plugs 69A and 69C are conducted after filling the via-holes 68A and 68C by a tungsten film by removing unnecessary tungsten film on the interlayer insulation film 68 by a CMP process. With such a CMP process, however, it is difficult to achieve completely flat surface for the via-plugs 69A and 69B and it is inevitable that there are formed depressions on the top part of the via-plugs 69A and 69C with a depth that can reach 20-50 nm.

Because such a depression provides profound effect on the crystal orientation of the ferroelectric capacitor formed thereon, the present embodiment deposits a Ti film on the interlayer insulation film 68 so as to fill such a depression with the (002) orientation. The Ti film thus formed are subsequently planarized by a CMP process after being converted to a TiN film of the (111) orientation by a nitridation processing.

As a result, with the ferroelectric memory of FIG. 7, there is interposed a TiN film 70a of (111) orientation between the interlayer insulation film 68 and the TiN film 70A so as to fill the depression at the top part of the via plug 69A. Further, there is interposed a TiN film 70c of the (111) orientation between the interlayer insulation film 68 and the TiN film 70C so as to fill the depression at the top part of the via-plug 69C. It should be noted that such TiN films 70a and 70c are patterned in the patterning step of FIG. 6K together with other films constituting the ferroelectric capacitors C1 and C2.

According to the present invention, it becomes possible to positively control the orientation of the ferroelectric films 73A and 73C to the (111) orientation even in the case there is formed a depression at the top part of the via-plugs 69A and 69C with the CMP process.

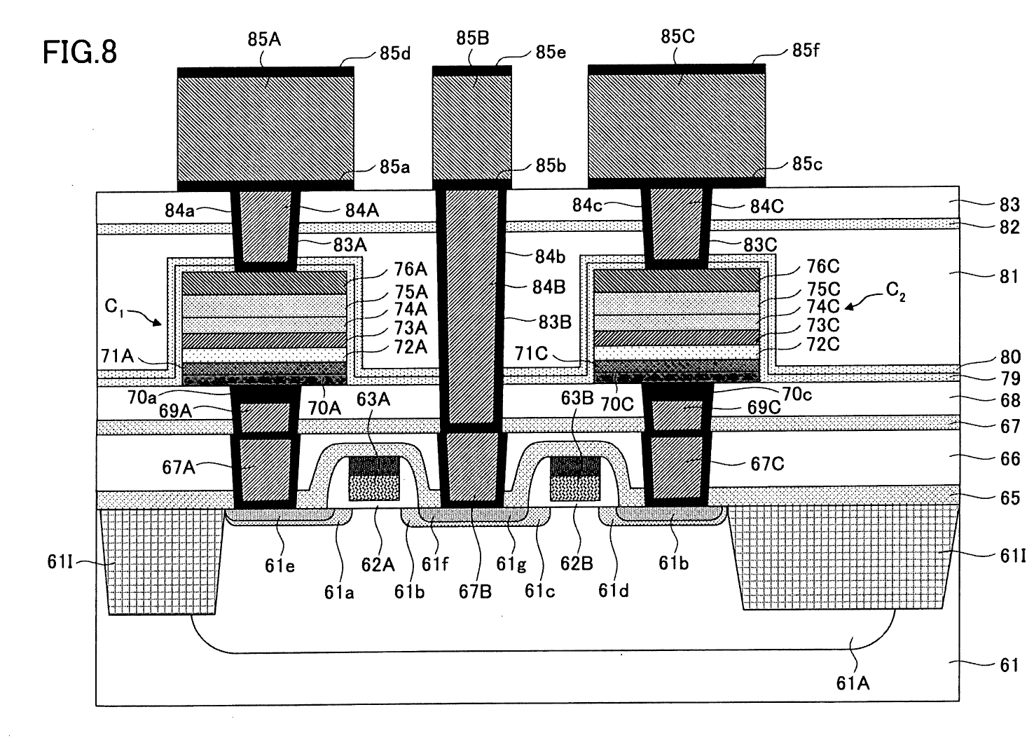

FIG. 8 shows the construction of a ferroelectric memory according to a modification of FIG. 7. In the drawing, those parts explained previously are designated by the same reference numerals and the description thereof will be omitted.

Referring to FIG. 8, the present embodiment removes the part of the TiN films 70a and 70c located above the interlayer insulation film at the time of planarizing the TiN films 70a and 70c by the CMP process. As a result, the TiN films 70a and 70c are remained only in the via-holes 68A and 68C. Otherwise, the present embodiment is identical to the embodiment of FIG. 7 and description thereof will be omitted.

### Fourth Embodiment

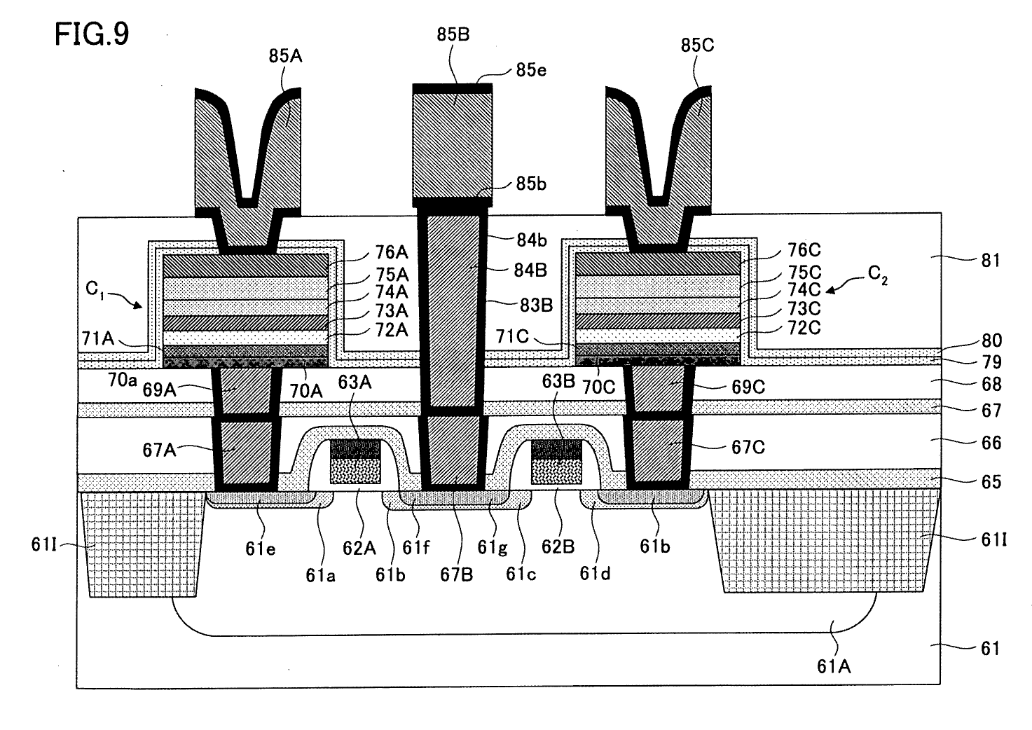

FIG. 9 shows the construction of a ferroelectric memory according to a fifth embodiment of the present invention.

Referring to FIG. 8, the present embodiment forms a via-hole exposing the via-plug 67B immediately in the interlayer insulation film 81 after the interlayer insulation film 81 is formed in the step of FIG. 6S and forms the via-plug 84B by filling the via-hole with tungsten.

Further, after formation of the via-plug 84B, an oxygen barrier film such as an SiON film is formed on the interlayer insulation film 81, and the contact hole exposing the upper electrode 76A of the ferroelectric capacitor C1 and the contact hole exposing the upper electrode 76C of the ferroelectric capacitor C2 are formed in the interlayer insulation film 81 in this state.

Further, the PZT films 74A and 75A of the ferroelectric capacitor C1 and the PZT films 74A and 75C of the ferroelectric capacitor C2 are annealed in the oxygen gas ambient via the contact holes for oxygen defect compensation. Thereafter, the oxygen barrier film is removed and the electrode patterns 85A, 85B and 85C are formed on the interlayer insulation film 81 respectively in correspondence to the upper electrode 76A of the ferroelectric capacitor Cl, the via-plug 84B and the upper electrode 76C of the ferroelectric capacitor C2.

Further, while the present invention has been explained heretofore with regard to preferred embodiments, the present invention is by no means limited to particular embodiments but various variations and modifications may be made without departing from the scope of the invention.

What is claimed is:

1. A semiconductor device comprising:
a conductive oxygen diffusion barrier film formed over a substrate;
a metal oxide film formed over said conductive oxygen diffusion barrier film for suppressing diffusion of Pb;
a lower electrode containing Pt formed over said metal oxide film;
a ferroelectric film containing Pb and formed over said lower electrode; and
an upper electrode formed over said ferroelectric film.

2. The semiconductor device as claimed in claim 1, wherein said ferroelectric film comprises a first film part contacting a surface of said lower electrode and a second film part formed over said first film part.

3. The semiconductor device as claimed in claim 1, wherein said first film part contains Ca or Sr further.

4. The semiconductor device as claimed in claim 1, wherein said metal oxide film comprises an insulating metal oxide and has a thickness allowing tunneling of carriers.

5. The semiconductor device as claimed in claim 4, wherein said metal oxide film comprises any of an aluminum oxide film, a titanium oxide film, a zirconium oxide film, a hafnium oxide film and a tantalum oxide film and has a thickness of 0.1 nm or more but not exceeding 5 nm.

6. The semiconductor device as claimed in claim 1, wherein said metal oxide film comprises a conductive metal oxide and has a thickness of 0.1 nm or more but not exceeding 100 nm.

7. The semiconductor device as claimed in claim 6, wherein said metal oxide film comprises any of a rhenium oxide film, a rhodium oxide film, an osmium oxide film, a platinum oxide film, an iridium oxide film, a ruthenium oxide film, a vanadium oxide film, a neodymium oxide film, an europium oxide film, a samarium oxide film, a SrRuO₂ film and a (La,Sr)CoO₃ film.

8. The semiconductor device as claimed in claim 1, wherein said conductive oxygen diffusion barrier film is formed on an orientation control film,
said orientation control film contains Ti, and said conductive oxygen diffusion barrier film contains Ti and Al and N.

9. The semiconductor device as claimed in claim 1, wherein said orientation control film comprises any of a Ti film of a (002) orientation or a TiN film of a (111) orientation.

10. The semiconductor device as claimed in claims 1, wherein said lower electrode comprises a Pt film.

11. The semiconductor device as claimed in claim 1, further comprising a MOS transistor formed on said substrate and an interlayer insulation film provided over said substrate so as to cover said MOS transistor, wherein said conductive oxygen diffusion barrier film is formed over said interlayer insulation film.

12. The semiconductor device as claimed in claim 11, wherein said lower electrode is formed over a via-plug formed in said interlayer insulation film in contact with a diffusion region of said MOS transistor.

13. A method of fabricating a semiconductor device having a ferroelectric film, comprising the steps of:
forming a MOS transistor on a silicon substrate;
depositing an interlayer insulation film over said silicon substrate so as to cover said MOS transistor;
forming a via-plug in said interlayer insulation film in contact with said diffusion region of said transistor;
forming a conductive oxygen diffusion barrier film over said via-plug;
forming a metal oxide film suppressing diffusion of Pb over said conductive oxygen diffusion barrier film;
forming a lower electrode film containing Pt as a primary component over said metal oxide film;
forming a ferroelectric film containing Pb over said lower electrode film;
forming an upper electrode over said lower electrode film.

14. The method of fabricating a semiconductor device as claimed in claim 13, wherein said step of forming said ferroelectric film comprises a step of forming a first ferroelectric film containing Pb by any of a sputter process or a sol-gel process, and a step of forming a second ferroelectric film containing Pb by an MOCVD profess.

15. The method of fabricating a semiconductor device as claimed in claim 13, wherein said metal oxide film is formed on said conductive diffusion barrier film by any of a sputtering process or ALD process in an amorphous state.

16. The method for fabricating a semiconductor device as claimed in claim 13, wherein said metal oxide film is formed by oxidizing a surface of said conductive oxygen diffusion barrier film.

17. The method for fabricating a semiconductor device as claimed in claim 13, wherein said metal oxide film comprises an insulating material and said step of forming said metal oxide film is conducted such that said metal oxide film has a thickness of 0.1 nm or more but not exceeding 0.5 nm.

18. The method for fabricating a semiconductor device as claimed in claim 13, wherein said metal oxide film comprises a conductive material and said step of forming said metal oxide film is conducted such that said metal oxide film has a thickness of 0.1 nm or more but not exceeding 100 nm.
